(19) United States
(12) Patent Application Publication
(10) Pub. No.: US 2025/0344352 A1
(43) Pub. Date: Nov. 6, 2025

(54) METHODS AND SYSTEMS FOR SUPPORT STRUCTURES

(71) Applicant: DPR Construction Inc., Redwood City, CA (US)

(72) Inventors: Erik Kneer, San Francisco, CA (US); Glenn Maguire, Christchurch (NZ); Sam Kinsey, Pasadena, CA (US); Scott Brown, Willows, CA (US); Scott Kiernan, Mechanicsville, VA (US); Langdon Lynch, Moseley, VA (US)

(21) Appl. No.: 19/197,664

(22) Filed: May 2, 2025

Related U.S. Application Data
(60) Provisional application No. 63/642,481, filed on May 3, 2024.
(60) Provisional application No. 63/703,801, filed on Oct. 4, 2024.

(51) Int. Cl. H05K 7/20; H05K 7/14

(52) U.S. Cl. CPC H05K 7/20745; H05K 7/1401

(57) ABSTRACT

Methods and systems for structural assemblies are provided. More specifically, brackets and securing members are provided that are operable to communicate with and secure structural members. The brackets, securing members, and related methods of assembly include the ability to translate a bracket or member with relative ease and quickly and efficiently secure the bracket and any elements connected to the bracket with at least one support member. Embodiments of the present disclosure are suitable for use in applications that require ground level assembly of items or features that are subsequently raised to a final height.

### CROSS-REFERENCE TO RELATED APPLICATIONS

This application claims priority under 35 U.S.C. § 119(e) to U.S. Provisional Patent Application Ser. No. 63/642,481 filed May 3, 2024, and to U.S. Provisional Patent Application Ser. No. 63/703,801 filed Oct. 4, 2024, both of which are incorporated herein in their entirety by reference.

### FIELD

Embodiments of the present disclosure relate to building methods and systems for data centers, server rooms and hot aisle containment systems. In certain embodiments, structures for supporting equipment and/or managing heat transfer within a data center are provided and at least portions of the structure(s) are formed using sustainable timber elements.

Other embodiments of the present disclosure relate to methods and systems for building structures and erecting building structures. In some embodiments, methods, systems, and devices comprise securing bracket structures that are operable to at least temporarily support an element in a raised vertical position.

### BACKGROUND

Various systems and devices exist for constructing data centers and server rooms which typically include spaced apart rows or aisles of equipment (e.g., servers and related hardware). The equipment intended to be housed or placed in the data center is known to generate a significant amount of heat that needs to be dissipated or otherwise managed to protect the equipment and create a reasonably comfortable environment for any persons entering the space. Known data center systems generally comprise “hot aisles” and “cold aisles”. The term “hot aisle” at least as used herein generally refers to corridors or spaces between or adjacent rows of cabinets and/or servers that are subject to an increased amount of thermal energy (e.g., a space between two opposed rear portions of cabinets having fans or venting features). While an entire data center or server room may be subject to increased thermal energy, it is known that hot aisles comprise areas of increased thermal energy even relative to a remainder of the data center. The term “cold aisle” at least as used herein refers to corridors or spaces of a data center that of reduced temperature relative to the hot aisle due to the positioning of the equipment in the center and/or the delivery of cooled, return air.

Existing systems related to data center construction and hot aisle containment features include, for example, U.S. Patent Application 2018/0338393 to Curtin et al., which is hereby incorporated by reference in its entirety.

Various systems and devices exist for securing structural members at various heights. For example, U.S. Pat. No. 9,022,332 to Stokes, which is hereby incorporated by references in its entirety, discloses a clamping system and support for securing to a column. Various brackets and braces are also known that, for example, join a horizontal beam (e.g., floor beam) to a vertical support.

Known systems, methods and devices, however, fail to disclose various aspects and benefits of the present disclosure as shown and described herein. For example, known devices fail to contemplate or provide devices and systems with ascending features that can be secured to a feature to be raised to a vertical position and/or which are selectively translatable and securable to a support member to provide at least one of temporary and permanent securement between a feature and a support member.

Known systems, methods and devices, however, fail to disclose various aspects and benefits of the present disclosure as shown and described herein.

### SUMMARY

There has been a long-felt and unmet need to provide systems, devices and methods for data centers, server rooms, and hot aisle containment areas that are sourced from and constructed from sustainable materials. There has further been a long-felt and unmet need to provide such systems that can be shipped efficiently in a deconstructed or partially deconstructed state and readily assembled on-site.

In addition, there has been a long-felt and unmet need to provide systems, devices and methods for connecting and supportive elements that enable quick and efficient erection of various structures including, for example, systems and devices that are translatable relative to an associated or adjacent structure or element and which are further operable to adjust or transition to a securing or secured mode such that the systems and devices are generally fixed or non-translatable relative to associated structures or features.

Embodiments of the present disclosure are well suited for and are adapted for use in building structures. For example, and without limitation, it is contemplated that brackets and securing members of the present disclosure are operable for use with and well suited for the formation and construction of data centers and hot aisle containment structures (“HAC”) that are known to comprise duct-like heat transfer structures that are provided at a raised height (e.g., vertically above a known cabinet for servers, etc.).

Various embodiments of the present disclosure are contemplated for use with timber structures and assemblies. It should be recognized, however, that inventive aspects of the present disclosure are not limited to use with specific structures, intended uses, materials etc. For example, while it is contemplated that embodiments of the present disclosure are suitable for use with erecting an at least partially timber-based HAC structure, systems, methods and devices of the present disclosure are further contemplated with steel or concrete structures and various applications.

In one or more embodiments according to the present disclosure, a clamping bracket for selective securement to a support is provided, the clamping bracket comprising: 1) a main body portion; 2) a displaceable member comprising a planar surface operable to contact and apply force to the support; wherein the main body portion comprises an angled surface and the displaceable member is slidingly translatable relative to the main body portion; and 3) a biasing member provided in communication with the displaceable member and operable to apply force to and displace the displaceable member at least in a first direction and secure the clamping bracket to the support.

In one or more embodiments, the displaceable member is slidingly translatable relative to the main body portion along a contact surface formed by the angled surface and a portion of the displaceable member.

In at least one embodiment, the contact surface comprises an angled bearing surface operable to direct a movement of the displaceable member.

In embodiments, the support comprises a column to which the clamping bracket is to be secured; the clamping bracket further comprising a plurality of interconnected members operable to surround the support.

In one or more embodiments, the clamping bracket further comprises a rod member extending through the displaceable member and the main body portion.

In embodiments, the biasing member is provided in communication with the rod member.

In embodiments the clamping bracket further comprising at least one fastener provided on the rod member and wherein the at least one fastener is operable to selectively limit a movement of the displaceable member.

In embodiments, the planar surface comprises at least one of a friction pad and a textured surface.

In one or more embodiments, the clamping bracket further comprises a fastener that extends through the bracket and into a member to which the bracket is to be secured to provide an anchorage in addition to the planar surface.

Embodiments according to the present disclosure contemplate providing a clamping bracket for selective securement to a vertical support member, the clamping bracket comprising: 1) a first portion comprising a first ramped surface; 2) a second portion that is displaceable relative to the first portion, the second portion comprising a planar surface operable to contact and apply force to the vertical support member to which the clamping bracket is to be secured; wherein the second portion comprises a second ramped surface in force transmitting communication with the first ramped surface and the first portion; and 3) a biasing member provided in communication with the second portion and operable to apply force to the second portion to displace the planar surface of the second portion in at least a first direction and secure the clamping bracket to the vertical support member.

In one or more embodiments, the first ramped surface and the second ramped surface comprise an angle of between approximately 45 and 80 degrees.

In one or more embodiments, the first portion further comprises a plurality of interconnected members operable to surround the vertical support member.

In one or more embodiments, the clamping bracket further comprises a rod member extending through the first portion and the second portion and wherein the biasing member is provided in communication with the rod member.

In one or more embodiments, the clamping bracket further comprises at least one fastener provided on the rod member and wherein the at least one fastener is operable to selectively limit a movement of the displaceable member.

In embodiments, the clamping bracket further comprises a fastener that extends through the bracket and into a member to which the bracket is to be secured to provide an anchorage in addition to the planar surface.

Embodiments according to the present disclosure comprise a clamping member for selective securement to a support, the clamping member comprising: 1) a first portion comprising a first angled surface; 2) a second portion that is displaceable relative to the first portion, the second portion comprising a planar surface portion and wherein the second portion is displaceable relative to the first portion; wherein the second portion comprises a second angled surface in force transmitting communication with the first angled surface and the first portion; and 3) a biasing member provided in communication with the first portion and the second portion and operable to apply force to the second portion to displace the second portion in at least a first direction and to secure the clamping member.

In embodiments, the clamping member further comprises at least one of hangar and a bracket extending from the first portion.

In one or more embodiments, the planar surface comprises a textured surface.

In embodiments, the clamping member further comprises a threaded rod extending through the first portion and the second portion and wherein the biasing member is provided in communication with the threaded rod.

In one or more embodiments, the clamping member further comprises a locking member provided on the threaded rod to selectively control a movement of the second portion.

In embodiments, the clamping member comprises an aperture for receiving a fastener and wherein the clamping member is operable to be secured to an object by a clamping force and the fastener.

In one or more embodiments according to the present disclosure, a clamping bracket for selective securement to a support is provided. The clamping bracket comprises a main body portion and a displaceable member comprising a planar surface operable to contact and apply force to a member to which the clamping bracket is to be secured. The main body portion comprises a first angled surface and the displaceable member comprises a second angled surface. The displaceable member is slidingly translatable relative to the main body portion along a contact surface formed by the first and second angled surfaces. A biasing member is provided in communication with the displaceable member and is operable to apply force to the displaceable member to displace the planar surface of the displaceable member in at least a first direction and secure the clamping bracket to the member to which the clamping bracket is to be secured.

In other embodiments, a clamping bracket for selective securement to a vertical support is provided that comprises a first portion comprising a first ramped surface and a second portion that is displaceable relative to the first portion. The second portion comprises a planar surface operable to contact and apply force to a vertical support member (for example) to which the clamping bracket is to be secured. The second portion comprises a second ramped surface in force transmitting communication with the first ramped surface and the first portion. A biasing member is provided in communication with the second portion and is operable to apply force to the second portion to displace the planar surface of the second portion in at least a first direction and secure the clamping bracket to the vertical support member to which the clamping bracket is to be secured.

In various embodiments, devices of the present disclosure comprise at least one ramped, angled or cammed surface. Movement of a displaceable member as shown and described herein is enabled by the angled surface. In certain embodiments, first and second angled or ramped surfaces are provided that communicate with one another and cause a movement of a displaceable component in at least two axes of movement (e.g., horizontal and vertical). As will be recognized by one of ordinary skill in the art, the angle of the surface will dictate the amount of vertical force required to displace the displaceable member. In some embodiments, the angle of the ramped surfaces comprises an angle of between approximately 70 and 80 degrees relative to horizontal to achieve vertical and horizontal movement of the displaceable member based on application of a vertical force from a biasing member (for example).

Embodiments of the present disclosure are well suited for and are adapted for use in data centers and server rooms. It should be recognized, however, that no limitation with respect to intended or final use of disclosed systems and methods is provided herewith unless specifically claimed. Methods, system, structures and features of the present disclosure are contemplated as comprising inventive and novel aspects regardless of their final use and application. For example, and without limitation, a containment structure as shown and described herein may be provided for use with a vent hood for conveying vapors from benchtop chemistry applications, conveying heat or smoke from culinary settings, or to generally improve HVAC systems.

Various embodiments of the present disclosure provide hot aisle containment systems and methods of using the same. In certain embodiments, systems and methods of the present disclosure contemplate the use of sustainable materials such as sustainable timber elements preferably formed from sustainable timber. As used herein, the term “timber” includes cut, raw, treated, composite, engineered timber elements and the like. In certain embodiments and depending on the ultimate application, timber elements of the present disclosure are contemplated as being provided with or treated with a flame-retardant.

In embodiments according to the present disclosure, a system for containing or conveying air in a data center comprises: 1) a plurality of vertical support columns; 2) a first planar member and a second planar member, wherein the first planar member and the second planar member comprises parallel spaced apart members at least partially defining a volume for at least one of containing and conveying air; and 3) a third planar member extending between the first and second planar members.

In embodiments, the third planar member is operable to provide stability to the system, and at least two of: one of the plurality of vertical support columns, the first planar member, and the third planar member are secured to one another.

In embodiments, at least one of the plurality of vertical support columns is secured to a substrate.

In one or more embodiments, at least one of the first planar member and the third planar member comprises a wood panel having a thickness of not more than 5.0 inches.

In embodiments, the third planar member is operable to provide torsional structural stability to the system and extends substantially perpendicularly to at least one of the first planar member and the second planar member.

In embodiments, the third planar member comprises a plurality of apertures to allow fluid to flow through at least a width of the third planar member.

In one or more embodiments, the system further comprises a securing member operable to secure at least two of: one of the plurality of vertical support columns, the first planar member, and the third planar member.

In at least one embodiment, the securing member is operable to secure at least one of the plurality of vertical support columns, the first planar member and the third planar member.

In embodiments, the securing member comprises at least one bracket operatively connected to the third planar member and at least one of the first planar member and the second planar member.

In one or more embodiments, the bracket is configured to at least partially surround at least one of the plurality of vertical support columns.

In embodiments, the securing member further comprises a locking element with a spring-loaded hinge operable to bias at least a distal end of the locking element toward the at least one of the plurality of vertical support columns.

In embodiments, the at least one of the plurality of vertical columns comprises a stop disposed on a desired vertical position along the at least one of the plurality of vertical columns; the stop being configured and dimensioned with the locking element to secure at least the securing member in the desired vertical position.

In embodiments according to the present disclosure, a method of constructing a hot air containment unit for a data center comprises: 1) providing a plurality of vertical support columns; 2) providing a first planar member and a second planar member in a parallel and spaced apart configuration such that the first and second planar members at least partially define a volume for at least one of containing and conveying air; 3) providing a third planar member extending between the first and second planar members; 4) securing the first, second and third planar members to one another; 5) vertically displacing the first, second and third planar members and the securing member to a desired vertical position; and 6) securing the first, second and third planar members and the securing member in the desired vertical position.

In embodiments, the first, second and third planar members are secured to one another by a securing member that at least partially surrounds a first one of the plurality of vertical support columns.

In one or more embodiments, the step of vertically displacing comprises using at least one of a scissor lift, a jack, and a motorized lift to vertically displace the first, second and third planar members, and the securing member to a desired vertical position.

In embodiments, securing the first, second and third planar members and the securing member in the desired vertical position comprises providing and securing a fastener through at least one of the securing member and the first column.

In at least one embodiment, at least one of the first column, the first planar member, the second planar member and the third planar member comprise a wood material.

Embodiments according to the present disclosure contemplate a method of installing a hot air containment structure for a data center comprising: 1) providing a hot air containment structure in a collapsed position and disposable into an expanded position, the hot air containment structure comprising: 2) a first planar member and a second planar member disposed in a parallel configuration; 3) a plurality of vertical support columns disposed between the first planar member and the second planar member, wherein at least one transverse panel disposed in a collapsed arrangement between the first planar member and the second planar member, and wherein the first planar member and the second planar member being adjacently disposed to the plurality of vertical support columns, at least one of the plurality of vertical columns disposed next to at least one different and adjacent one of the plurality of vertical columns; 4) disposing the hot air containment structure into the expanded position, comprising: 4a) disposing the transverse panel into an extended orientation such that the first planar member and the second planar member are in a spaced apart relation to one another with the at least one transverse panel disposed between them.

In at least one embodiment of the method, disposing the hot air containment structure into the expanded position further comprises: 4b) disposing the plurality of vertical support columns from an initial and at least partially folded arrangement into an expanded arrangement comprising at least a first of the plurality of vertical support columns adjacently disposed to the first planar member and at least a second of the plurality of vertical support columns adjacently disposed to the second planar member.

In embodiments of the method, the transverse panel comprises a first segment pivotally movable to a second segment.

In embodiments of the method, the first segment pivotally movable to the first planar member and the second segment pivotally movable to the second planar member.

In one or more embodiments of the method, the first planar member, the second planar member and the transverse panel are movable in a vertical direction relative to the plurality of vertical support columns.

In embodiments, the method further comprises: 5) lifting the first planar member, the second planar member and the transverse panel to a desired vertical position.

Embodiments of the present disclosure provide for data center structures and methods of constructing the same. In one embodiment, a system for containing or conveying air in a data center is provided that comprises a plurality of vertical support columns and a first planar member and a second planar member. The first planar member and the second planar member comprise parallel spaced apart members at least partially defining a volume for at least one of containing and conveying air. A third planar member is provided that extends between the first and second planar members and wherein the third planar member is operable to provide torsional structural stability to the system. A securing member is provided to secure a vertical support column, the first planar member, and/or the third planar member.

In one embodiment, a method of constructing a hot air containment unit for a data center is provided that comprises providing a plurality of vertical support columns; providing a first planar member and a second planar member in a parallel and spaced apart configuration such that the first and second planar members at least partially define a volume for at least one of containing and conveying air; providing a third planar member extending between the first and second planar members; wherein the first, second and third planar members are secured by a securing member and wherein the securing member at least partially surrounds a first column of the plurality of columns; vertically displacing the first, second and third planar members and the securing member to a desired vertical position; and securing the first, second and third planar members and the securing member in the desired vertical position by providing and securing a fastener through at least one of the securing member and the first column.

In various embodiments, improved insulative properties are provided at least in part through the provision of wood structures and hot aisle containment structures formed at least partially from wood. Conventional hot aisle containment systems are known to rely heavily or exclusively on metals (e.g., various steels) which are known conductors of thermal energy. In contrast, various wood and timber materials contemplated for use with embodiments of the present disclosure provide enhanced insulative properties and are suited for containing air to be conveyed and/or cooled. Embodiments of the present disclosure thus contemplate air containment units comprising at least one material with an R value known to be greater than at least one of aluminum and steel.

The present disclosure contemplates and discloses methods and system for structural assemblies. Systems and methods of the present disclosure provide various benefits related to efficiency and safety. For example, in certain embodiments, systems and related methods of constructing or forming the same are provided such that preformed features are provided at an installation site and/or various method steps and activities are operable and intended to be performed at ground level. The lifting of panels and various features of the present disclosure is performed sequentially thereafter. Safety and efficiency are thus improved where overhead or “at-height” operations are minimized thereby reducing the risks associated with such overhead operations and related equipment.

Embodiments of the present disclosure contemplate the provision of timber materials including, for example, wood posts and panels. These materials and structures provide enhanced versatility and a near infinite number of options for mounting hardware and fasteners and related versatility for customization, upgrades, retrofits, remodels, etc. wherein a user or owner is not constrained by the limited number of options provided by known systems. In various embodiments, at least one vertical support member is provided that comprises wood and wherein additional system elements are raised and secured to the at least one vertical support member at any desired position. The wood support member provides a substantially homogeneous element along its height wherein a user may secure elements at an infinite number of locations along said height, thereby providing improved ease and efficiency in installation.

Various features, components, elements, etc. of the present disclosure are contemplated as comprising wood timber. Such components are contemplated as comprising various sizes (e.g., thickness, width, etc.) of solid lumber or engineered wood product and no limitation of wood species (e.g., fir, larch, pine, spruce, etc.) is provided. Such elements are further contemplated as comprising, for example, glue laminated timber (“GLT” or “glulam”), cross laminated timber (“CLT”), veneer laminated timber (“VLT”), laminated veneer lumber (“LVL”), mass ply panels (“MPP”), mass ply lumber (“MPL”), dowel laminated timber (“DLT”), oriented strand board (“OSB”), and/or plywood. Further embodiments comprise “built-up” posts or panels that are composite elements of one or more of the above lumber or engineered wood products and associated hardware (e.g., a panel made of a solid sawn wood frame sheathed by plywood or OSB on one or both sides). Accordingly, the various features, elements and components shown and described herein are contemplated as comprising one or more of the materials or an equivalent even if a specific material is not called out. It should also be recognized that while various components of systems of the present disclosure are contemplated as comprising wood timber, such features are alternatively contemplated as comprising a metal or other material that is structurally suitable for a given intended purpose.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In addition, the materials, methods, and examples are illustrative only and are not intended to be necessarily limiting.

### DESCRIPTION OF THE DRAWINGS

Those of skill in the art will recognize that the following description is merely illustrative of the principles of the disclosure, which may be applied in various ways to provide many different alternative embodiments. This description is made for illustrating the general principles of the teachings of this disclosure and is not meant to limit the inventive concepts disclosed herein.

The accompanying drawings, which are incorporated in and constitute a part of the specification, illustrate embodiments of the disclosure and together with the general description of the disclosure given above and the detailed description of the drawings given below, serve to explain the principles of the disclosure.

FIG. 1 is a perspective view of a building structure contemplated for use with embodiments of the present disclosure.

FIGS. 2A-2C are a series of perspective views showing a sequence of erecting a structure contemplated for use with embodiments of the present disclosure.

FIG. 3A is a perspective view of a connecting and securing component and associated features according to one embodiment of the present disclosure.

FIG. 3B is a detailed perspective view of the component and associated features according to the embodiment of FIG. 3A.

FIG. 4A is a perspective view of connecting and securing components and associated features according to one embodiment of the present disclosure.

FIG. 4B is a detailed perspective view of a component and associated features according to the embodiment of FIG. 4A.

FIG. 4C is a detailed perspective view of a component and associated features according to the embodiment of FIG. 4A.

FIG. 5A is a perspective view of a connecting and securing component according to one embodiment of the present disclosure.

FIG. 5B is a perspective view of connecting and securing component according to the embodiment of FIG. 5A.

FIG. 5C is a perspective view of connecting and securing component according to the embodiment of FIG. 5A.

FIG. 5D is a perspective view of connecting and securing component according to the embodiment of FIG. 5A.

FIG. 6 is a perspective view of connecting and securing component according to one embodiment of the present disclosure.

FIG. 7 is a cross-sectional perspective view of the component of FIG. 6.

FIG. 8 is a top plan view of a component and related structural elements according to one embodiment of the present disclosure.

FIG. 9 is a perspective view of a connecting and securing component according to one embodiment of the present disclosure.

FIG. 10 is a perspective view of a connecting and securing component according to the embodiment of FIG. 9.

FIG. 11 is a side elevation view of a connecting and securing component according to the embodiment of FIG. 9.

FIG. 12 is a rear elevation view of a connecting and securing component according to the embodiment of FIG. 9.

FIG. 13 is a cross-sectional side elevation view of a connecting and securing component according to the embodiment of FIG. 9.

FIG. 14 is a detailed cross-section view of a connecting and securing component according to the embodiment of FIG. 9.

FIG. 15 is a perspective view of a data center according to an embodiment of the present disclosure.

FIG. 16 is an elevation view of a data center according to an embodiment of the present disclosure.

FIG. 17 is a perspective view of a data center according to one embodiment of the present disclosure.

FIG. 18 is an illustration of a construction and installation sequence of data center features according to an embodiment of the present disclosure.

FIG. 19A is a top plan view of an installation sequence for a data center according to an embodiment of the present disclosure.

FIG. 19B is an elevation view of an installation sequence for a data center according to an embodiment of the present disclosure.

FIG. 20 is an elevation view of a data center structure according to an embodiment of the present disclosure.

FIG. 21 is a top plan view of components of a data center structure according to an embodiment of the present disclosure.

FIG. 22 is a perspective view of a data center structure according to an embodiment of the present disclosure.

FIG. 23 provides a series of views of a component of a data center structure according to an embodiment of the present disclosure.

FIG. 24 provides a series of views of a component of a data center structure according to an embodiment of the present disclosure.

FIG. 25 is a top plan view of a component of a data center structure according to an embodiment of the present disclosure.

FIG. 26 is a perspective view of a component of a data center structure according to an embodiment of the present disclosure.

FIG. 27 is a top plan view of components of a data center structure according to an embodiment of the present disclosure.

FIG. 28 is a top plan view of a component of a data center structure according to an embodiment of the present disclosure.

FIG. 29 is a perspective view of a component of a data center structure according to an embodiment of the present disclosure.

FIG. 30 is a perspective view of a component of a data center structure according to an embodiment of the present disclosure.

FIG. 31 is an elevation view of a component of a data center structure according to an embodiment of the present disclosure.

FIG. 32 is an elevation view of a system for a data center structure according to an embodiment of the present disclosure.

FIG. 33 is a series of views illustrating an installation sequence of a data center structure according to an embodiment of the present disclosure.

FIG. 34A is a perspective view of a structural component according to an embodiment of the present disclosure.

FIG. 34B is a perspective view of a structural component according to an embodiment of the present disclosure.

FIG. 35 is a top plan view of a structural component according to an embodiment of the present disclosure.

FIG. 36 is a top plan view of a structural component according to an embodiment of the present disclosure.

FIG. 37A is a top plan view of a structural component according to an embodiment of the present disclosure.

FIG. 37B is an elevation view of components according to an embodiment of the present disclosure.

FIG. 38A is an elevation view of components according to an embodiment of the present disclosure.

FIG. 38B is a top plan view of a structural component according to an embodiment of the present disclosure.

FIG. 39 is a top plan view of a data center assembly according to an embodiment of the present disclosure.

FIG. 40 is a diagrammatic representation of a method of constructing a hot air containment unit for a data center according to one embodiment of the present disclosure.

FIG. 41 is a diagrammatic representation of a method of installing a hot air containment unit for a data center according to one embodiment of the present disclosure.

The drawings are not necessarily to scale. In certain instances, details that are not necessary for an understanding of the disclosure or that render other details difficult to perceive may have been omitted. It should be understood, of course, that the disclosure is not necessarily limited to the particular embodiments illustrated herein.

### DETAILED DESCRIPTION

Reference to an element by the indefinite article “a” or “an” does not exclude the possibility that more than one element is present, unless the context clearly requires that there be one and only one element. The indefinite article “a” or “an” thus usually means “at least one.”

As used herein, “about”, “approximately”, and/or “substantially” means within a statistically meaningful range of a value or values such as a stated concentration, length, molecular weight, pH, sequence identity, time frame, temperature or volume. Such a value or range can be within an order of magnitude, typically within 20%, more typically within 10%, and even more typically within 5% of a given value or range. The allowable variation encompassed by “about”, “approximately”, and/or “substantially” will depend upon the particular system under study, and can be readily appreciated by one of skill in the art.

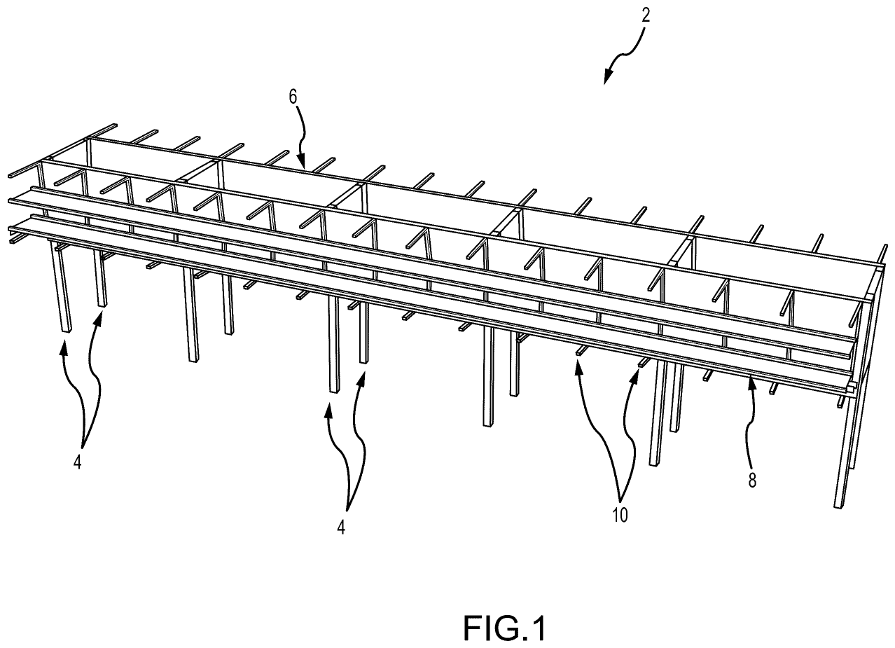

FIG. 1 is a perspective view of a structure 2 to be erected and/or assembled. As shown in FIG. 1, the structure 2 is contemplated as comprising a HAC system but it will be recognized that the structure may comprise various forms. The structure 2 illustrated in FIG. 1 comprises a plurality of vertical support members 4. The vertical support members 4 are operable to provide structural support to various components including, for example, a HAC structure 6 that is provided in a vertically elevated position (relative to at least a ground or floor surface). The HAC structure 6 is contemplated as comprising, for example, a pre-fabricated HAC unit of various sizes, weights, proportions etc. The structure 2 is contemplated as comprising additional features and structures including, for example, cable trays 8 and associated support members 10. The structure 2 of FIG. 1 is provided for illustrative purposes and provides an example of a structure that requires or benefits from support members in accordance with embodiments of the present disclosure and as are shown and described herein. For example, HAC structures 6 are generally operable and intended to be built or formed at-grade, or on a floor, slab or other planar surface, and then lifted or raised into their desired final position. Once provided in a final position, the HAC 6 and associated features are secured by, for example, providing a secure connection between the HAC 6 and one or more of the vertical support members 10 with which the HAC is vertically translatable.

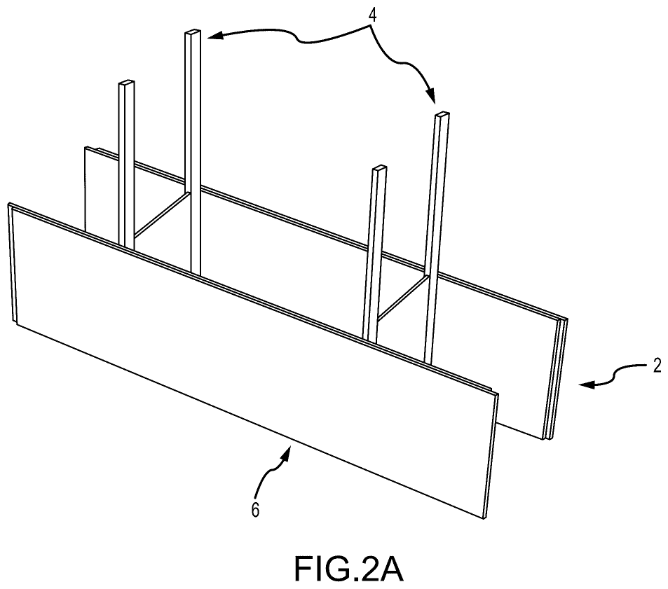

FIGS. 2A-2B are perspective views of a partially erected structure 2 contemplated as being provided in combination with embodiments and features of the present disclosure. As shown, the structure 2 comprises a plurality of vertical support members 4 to which additional elements are to be secured. Specifically, a HAC structure 6 is contemplated as being assembled or constructed at or near ground level and subsequently raised to a desired position. The HAC structure 6 is to be secured to the vertical support members 4 and/or additional components once positioned in its final desired location (FIG. 2C). Bracket and support members of the present disclosure and as will be shown and described herein are useful and suitable for such applications, including for enabling or allowing lifting of the HAC and for securing the HAC in its desired position.

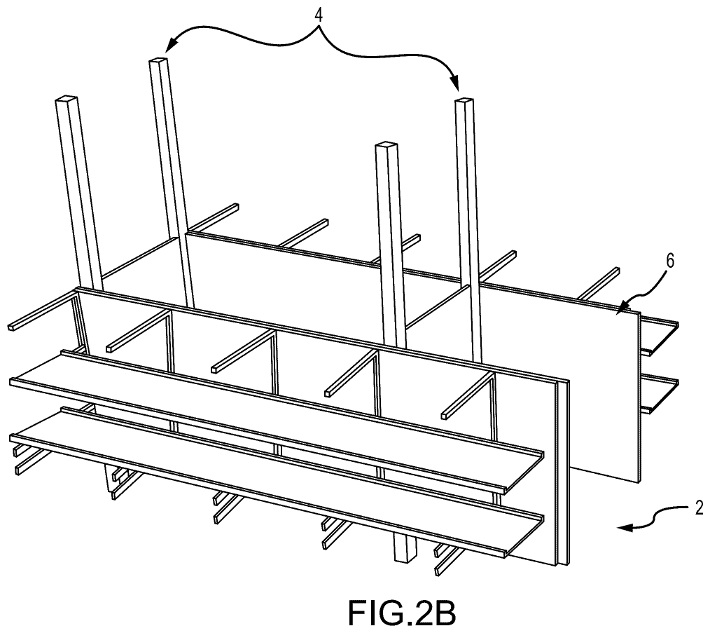

FIG. 3A is a perspective view of a vertical support member 20 and first and second structural members 22a, 22b. The structural members 22a, 22b are shown as planar members but no limitation with respect to the shape, size, number, etc. of structural elements is provided. One of ordinary skill in the art will understand that securing members and inventions disclosed herein may be used with various applications are not limited to use with planar structural elements. A securing bracket 24 in accordance with one embodiment of the present disclosure is provided. The securing bracket 24 is operable to be secured to the first and second structural members 22a, 22b and allow for translation of the members 22a, 22b and the bracket relative to the support member 20 in at least a first arrangement.

As shown in FIG. 3A, the bracket 24 comprises flanges 26a, 26b with apertures to allow fasteners (e.g., screws) to secure the bracket 24 to the structural elements 22a, 22b. The connected bracket 24 and structural elements 22a, 22b are thus translatable with respect to the support 20 in the arrangement of FIG. 3A as none of those components are secured to the support 20 in this arrangement. The bracket 24 comprises a biased pawl 28. At least one of a tang, ratchet, and a projection 30 is provided and secured to the vertical support member 20. Although a single projection 30 is shown, it should be recognized that numerous projections are contemplated as are ratchet members that provide a plurality of vertical positions in which the bracket 24 and associated elements may be secured. As shown in the detailed view of FIG. 3B, the pawl 28 comprises an angle and biased distal end such that the pawl 28 is operable to translate over and past the projection 30. The pawl 28 is deflected upon making initial contact with the projection (i.e., in the direction of travel wherein the bracket 24 is translated from FIG. 3A to FIG. 3B) and such that the pawl 28 and bracket 24 translate at least partially beyond the projection 30.

As shown in FIG. 3B, the pawl 28 is biased and a distal end thereof is operable to return to an angled position wherein the pawl contacts the projection 30 in a manner that substantially prevents reverse (i.e., downward) translation of the bracket 24 and associated structural members 22a, 22b. The bracket 24 and its structure and described method(s) of use provide for an ascending bracket wherein elements may be raised and translated, then secured at a desired or preferred vertical position.

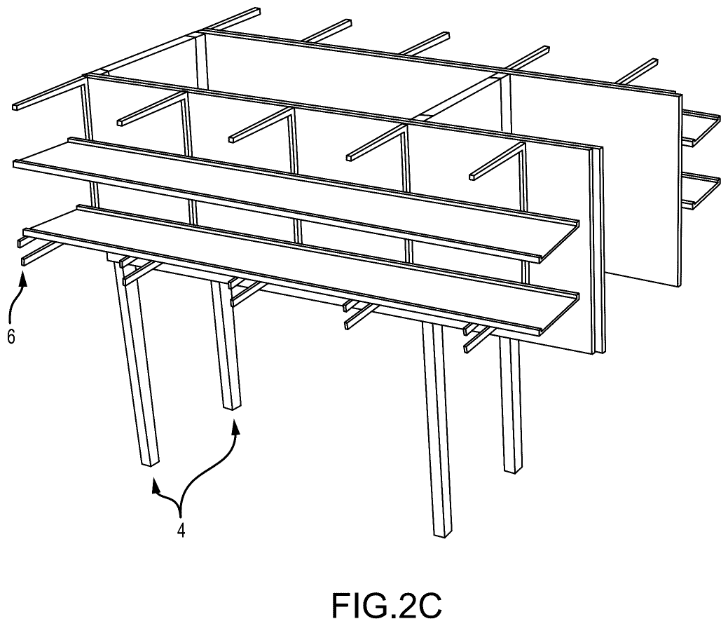

FIGS. 4A-4C are perspective views of bracket members 40a, 40b according to another embodiment of the present disclosure. As shown, the brackets are operable to at least partially surround a structural member 42 and comprise a plurality of flange members to selectively connect to additional structural members 44, 46. The brackets 40a, 40b generally comprise the same structure. A first bracket 40a is provided at an upper portion of the depicted assembly and a second bracket 40b is provided at a lower portion of the depicted assembly. The brackets 40a, 40b are contemplated as comprising the same structure and wherein the brackets are flipped or inversed as shown. The brackets 40a, 40b comprise a plurality of flange members 45. Apertures are provided throughout the surface(s) of the brackets 40a, 40b.

Once the structural members 42, 44, 46 are provided in the final, intended position, the members may be secured to one another and the brackets 40a, 40b by providing fasteners through the apertures of the bracket and into the structural members. Various embodiments of the present disclosure contemplate brackets that comprise one or more metals to provide sufficient structural and material strength, but no limitation with respect to the preferred material of the bracket(s) is provided. Additionally, various embodiments of the present disclosure contemplate that structural elements and features of the present disclosure comprise wood or timber. However, various materials and combinations of materials are contemplated, and it will be recognized that inventive aspects of the present disclosure are not limited to specific materials.

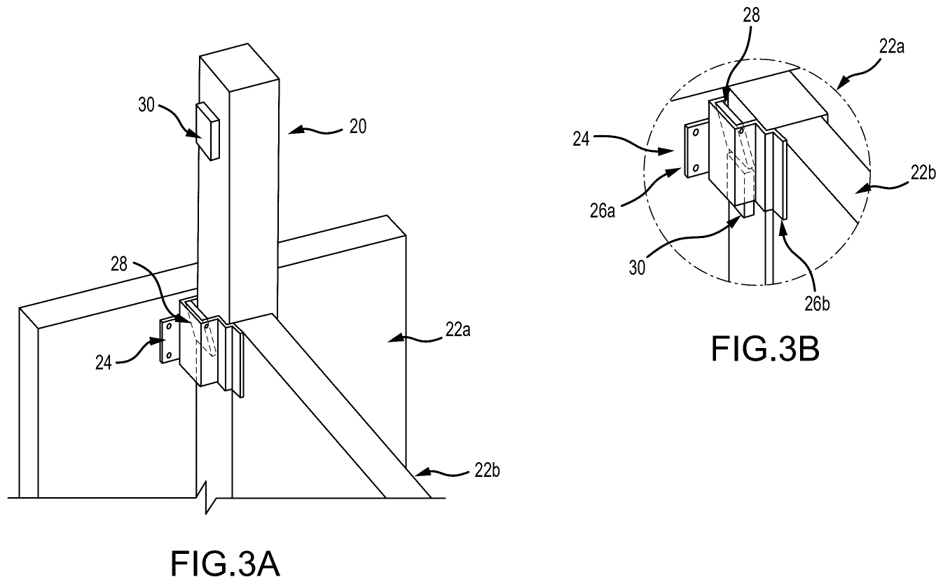

FIGS. 5A-5D are perspective views of an ascending bracket 50 according to another embodiment of the present disclosure. As shown, the bracket 50 comprises a plurality of planar members 52a, 52b, 52c, 52d arranged in a manner that generally forms an interior void 54. As shown, the interior void 54 comprises a space that is open at its top and bottom and which is operable to receive a structural member (e.g., a post of rectilinear cross-section). At least one of the planar members is operable to be secured to an additional component (e.g., a panel, not shown in FIGS. 5A-5D). The bracket 50 comprises a clamping plate 56 that is operable to be displaced relative to at least one of the remainder of the bracket and a member to which the bracket is to be secured. More specifically, the clamping plate 56 is moveable in a direction defined by a slot 58 provided in the bracket sidewalls 52a, 52b and wherein a pin or bearing member 60 is provided in communication with the slot 58.

The arrangement shown in FIG. 5A comprises a first unsecured position of the bracket 50. It is contemplated that the bracket 50 is provided in combination with a structural member and wherein a clearance is provided between the bracket 50 and the associated structural member to allow for translational movement of the bracket 50 relative to the structural member. For example, it is contemplated that a clearance of between approximately 5 mm and 0.1 m is provided between surfaces of the support and the bracket. In some embodiments, a clearance of approximately 15 mm is provided to allow for movement of the bracket and to permit the bracket 50 to be secured to the structural member upon displacement of the clamping plate 56 as shown and described herein.

FIG. 5B illustrates a second position of the bracket 50 wherein the clamping plate 56 has been displaced from the initial position. More specifically, when the bracket 50 and associated elements have been provided in a final or desired position, the bracket 50 may be transitioned or activated such that the clamping plate 56 is displaced vertically and horizontally (as shown in FIG. 5B) and such that the plate 56 is brought into contact with a support or structural member provided within the interior void 54, thereby securing the bracket 50 and any associated elements to the structural member.

In various embodiments, including those shown in FIGS. 5A-14 for example, the bracket is activated (i.e., converted from an initial position to a clamping position) by an application of force upon the face of the clamping plate (56 in FIG. 5A). More specifically, the bracket 50 is contemplated as being provided around or in close proximity to a structural member (e.g., a post) and is slid or translated upwardly along the structural member. Contact between the structural member and the clamping plate 56 provides a frictional force that biases the plate 56 downwardly. The ramp or cammed surfaced 56 is provided and is operable to cause the plate 56 to move or be biased or urged downwardly and away from the post (i.e., toward the position of FIG. 5A). When the bracket is brought to or near its final position, downward force upon the bracket 56 (e.g., as applied by a user and/or the force of the gravity) provides an opposition frictional force wherein the plate 56 is urged upwardly at least with respect to a remainder of the bracket 50. The upward bias or force on the plate and the cammed surfaced 58 urges the plate toward a locked position (FIG. 5B).

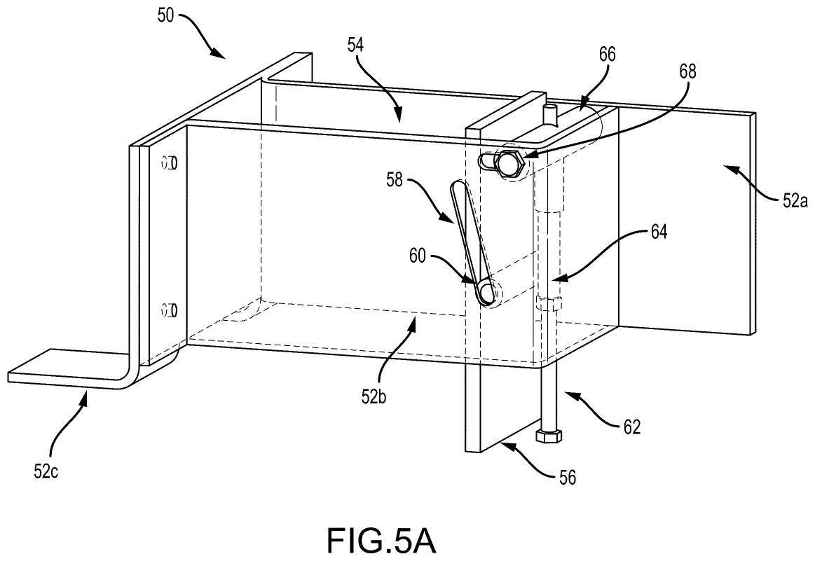

In some embodiments, including those shown in FIGS. 7 and 11-14, a spring or biasing member is provided that biases or urges the clamping plate toward its closed position. A spring force is provided that is not so great as to exceed the downward forces applied to it when raising or lifting the bracket and wherein the aforementioned frictional force applied during lifting is sufficient to bias or move the plate toward the unsecured position. When the downward force on the plate that is provided by frictional engagement between the plate and the post is removed (i.e., lifting of the bracket and associated elements has ceased), the spring is operable to displace the clamping plate in the X and Y directions (see FIG. 7) to provide a securing or clamping force between the face of the plate and the post or column.

As shown in FIGS. 5A-5C, the bracket 50 further comprises a rod 62 along which the clamping plate 56 is translatable and/or securable. In embodiments, the rod 62 comprises a threaded rod. A bushing 64 is provided that connects the clamping plate 56 to the rod 62. The rod 62 is horizontally translatable along with the clamping plate 56. A horizontal bushing 66 and slot 68 are provided to enable and allow horizontal displacement of the rod 62. A securing of the clamping plate 56 is achieved by displacing the threaded rod 62 (see transition from FIG. 5B to 5C) and tightening a lock nut 70 provided on the threaded rod 62 to secure the position of the system and substantially prevent reverse translation of the rod 62 and/or plate 56.

As shown in FIG. 5D, wherein the bracket 50 is provided in a secured position, a downward force as may be imparted by settling of components and/or gravity, which for example, causes an increased compression force to be applied to the structural member (not shown) by the clamping plate 56. In embodiments, a bearing surface of the slot 58 receives force from the bearing member 60 and the plate 56 is forced toward the structural member.

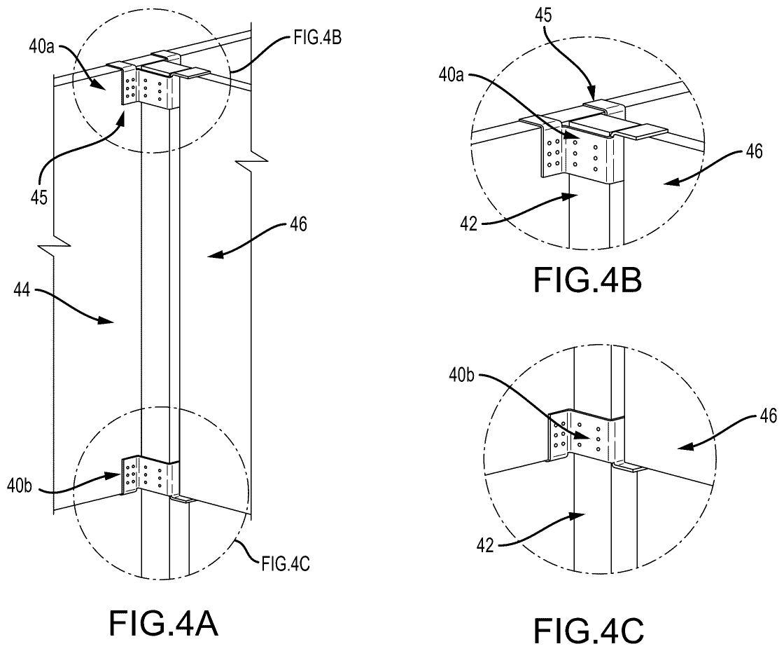

FIG. 6 is a perspective view of a bracket 70 according to another embodiment of the present disclosure. As shown, the bracket 70 comprises a plurality of panels 72a, 72b, 72c and a securing member 74. The securing member 74 comprises a moveable clamping plate 76 that is operable to apply a force to an associated element (e.g., a structural support or post) and secure the bracket 70 and any additional, associated elements at a desired position. As shown, one or more of the panels 72 of the bracket 70 are contemplated as comprising holes or apertures for receiving hardware to secure the bracket to one or more additional elements. As discussed, one or more structural elements (e.g., panels) are contemplated as being secured to a bracket of the present disclosure. A void space 78 is provided which is contemplated as accommodating various structural members (e.g., posts) to which the bracket 70 is translatable and/or selectively securable. The clamp is selectively securable to the structural member by at least one of a clamping force provided by the plate 76 and by hardware (e.g., fasteners).

FIG. 7 is a cut-away perspective view of the bracket 70 according to the embodiment of FIG. 6 to illustrate various portions and features of the bracket 70. As shown, the bracket 70 comprises a securing mechanism 74 comprising a clamping plate 76 that is displaceable and operable to contact at least one of a surface and a member to which the bracket 70 is to be secured. As shown, the bracket 70 comprises a plurality of members 72a, 72b (not shown in FIG. 7), 73c that collectively surround and/or form a void space 78 that is operable to receive a structural member (e.g., a vertical post or column). A tolerance or gap is preferably provided between any associated structural member and surface(s) of the clamp 70. The clamp 70 is thus translatable relative to the structural member. Once provided in a desired position the clamp 70 and connected components can be secured to the column. Securing of the clamp 70 is accomplished by displacing the plate 76 in an x and y direction. More specifically, a first portion 80 of the clamp is moveable relative to at least a second portion 82 and wherein an angled bearing surface 84 is provided to cause a movement of the plate 76 and first portion 80 in the x and y direction. A rod member 81 is provided that extends through the first 80 and second portion 82. A biasing member 88 is positioned between a flange 86 of the rod member 81 and a collar 90. The biasing member 88 is thus operable to impart an upward force (i.e., in the y direction) to the first portion 80 which is converted to a diagonal movement of the plate 76 by the bearing or cam surface 84.

As is further shown in FIG. 7, a void space 77 is provided within the first portion 80 to provide for and accommodate a movement of the plate 76 in the x-direction. The rod member 81 is contemplated as comprising a member that remains stationary in the x-direction and the plate 76 is allowed to move in the x-direction relative to the rod member 81 at least in part due to the provision of the void space 77.

The normal force and an associated frictional clamping force applied by the plate 76 to an associated structural member will be dependent upon the spring force of the biasing member 88 and/or the angle of the bearing surface 84. It is further contemplated that a surface of the clamping plate 76 is structured, treated, finished, etc. to increase the weight bearing capacity of the clamp 70. For example, it is contemplated that a surface of the plate 76 comprises projections (e.g., teeth, rasps, knurling, etc.) and/or high friction material(s) (e.g., rubber) to increase the frictional force and/or strength of a connection. It is further contemplated that the connection between the clamp 70 and a structural member is permanently or semi-permanently secured by the provision of fasteners. Various portions of the clamp are contemplated as comprising apertures for receiving screws or similar fasteners to provide additional securement of the clamp and associated members.

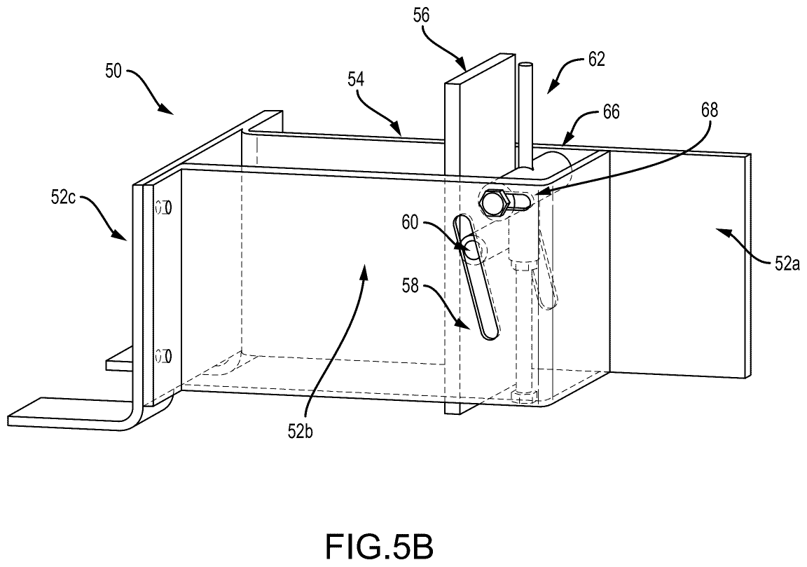

FIG. 8 is a top plan view of an assembly comprising a clamp 100 and a plurality of structural members 102, 104, 106. The clamp 100 is contemplated as comprising any one of the various embodiments of clamps shown and described herein. As shown in FIG. 8, the clamp 100 is provided such that it envelops a structural member 102. The structural member 102 is contemplated as comprising a post of rectangular cross section. Additional structural members 104, 106 are contemplated as being secured to and translatable with the bracket 100. The second and third structural members 104, 106 are contemplates as comprising panel members such as may be useful for formation and assembly of a HAC structure. As shown, the second and third structural members 104, 106 extend substantially perpendicular to one another but no limitation with respect to this relative positioning is provided herewith. In a first position, wherein the bracket 100 and second and third structural members 104, 106 are moveable relative to the column 102, a gap, spacing or tolerance is provided between the clamp 100 and the column 102. As shown, at least a first and second gap 110a, 110b is provided between the clamp and the column 102 such that the clamp 100 and the second and third structural members 104, 106 are moveable relative to the column 102 and at least until the clamp 100 is secured by the various methods and structural features shown and described herein.

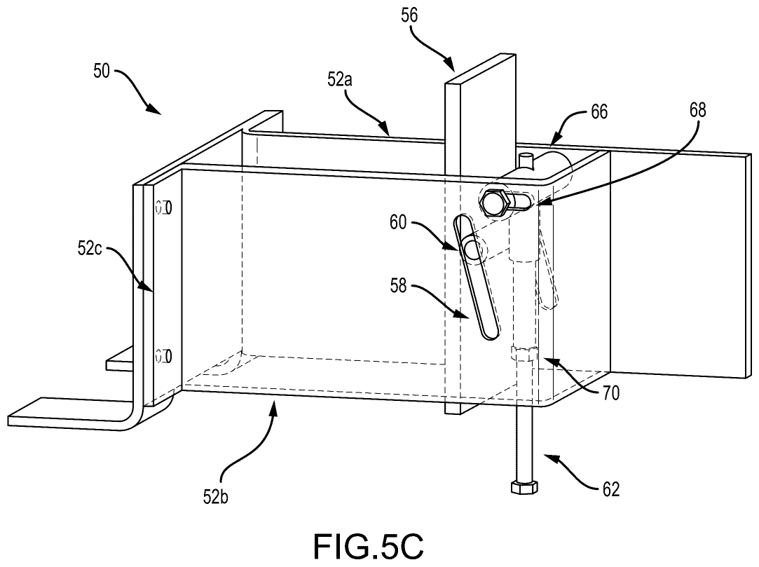

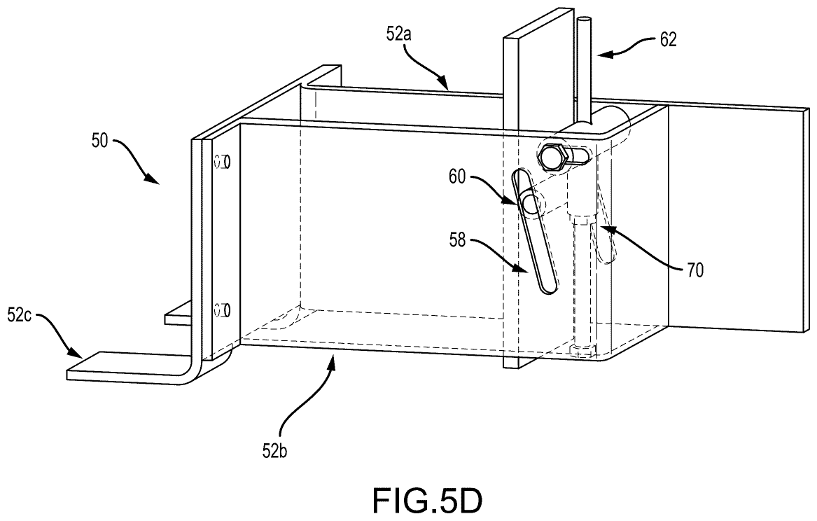

FIGS. 9-10 are front and rear perspective views, respectively, of a clamping bracket 120 according to an embodiment of the present disclosure. As shown, the bracket 120 comprises a displaceable clamping plate 122 that is translatable relative to a main body portion 124 according to principles and concepts as shown and described herein. The clamping plate 122 preferably comprises a textured or coated surface 123 with a desired coefficient of friction for advantageous communication with an associated structural member or other object. More specifically, the surface 123 of the plate 122 is contemplated as slidingly engaging a structural object when the bracket is translated upwardly so as to urge the plate 122 downwardly along the ramped surface 130 and urge or bias the system toward an open position. When an upward movement of the system is ceased and an associated force of friction is removed from the system, a biasing member 126 is provided in communication with a rod member 128 and is operable to provide an upward force upon the clamping plate 122 whereupon the plate 122 is translated vertically and horizontally by virtue of the ramped surface 130. Accordingly, as provided in various embodiments of the present disclosure, a transition from an unlocked or upwardly translatable arrangement to a clamped or locked arrangement occurs automatically and by a combination of device features and the force of gravity. Various embodiments contemplate that additional securing features (e.g., fasteners and additional hardware) are or can be provided to secure the bracket and any associated elements in a final position. In some embodiments, however, it is contemplated that the clamping force of the bracket alone is sufficient to support a load in a desired position.

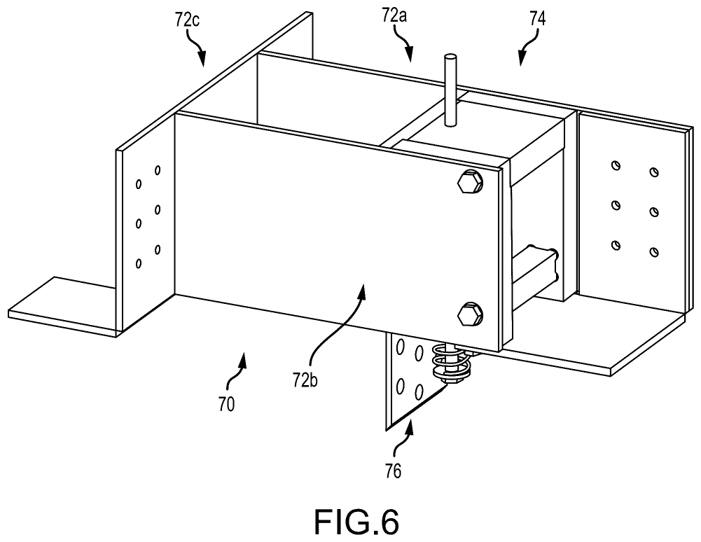

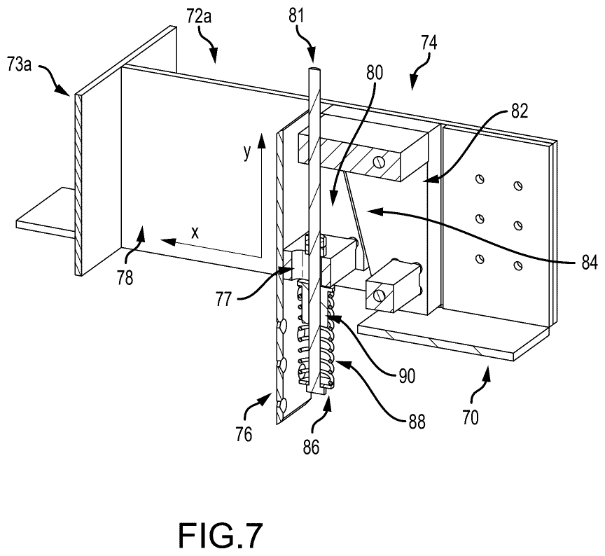

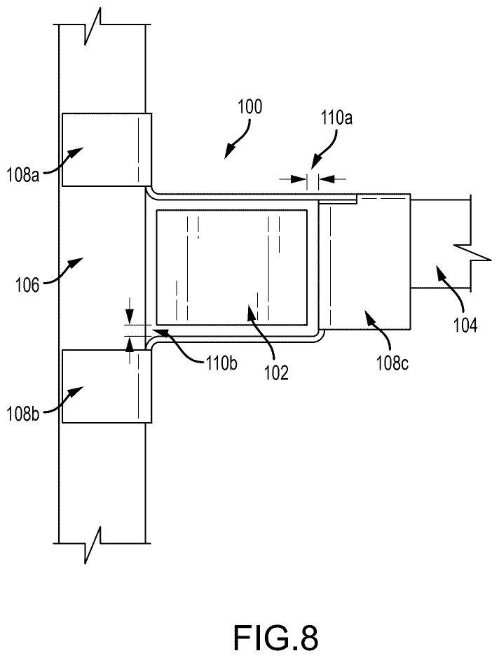

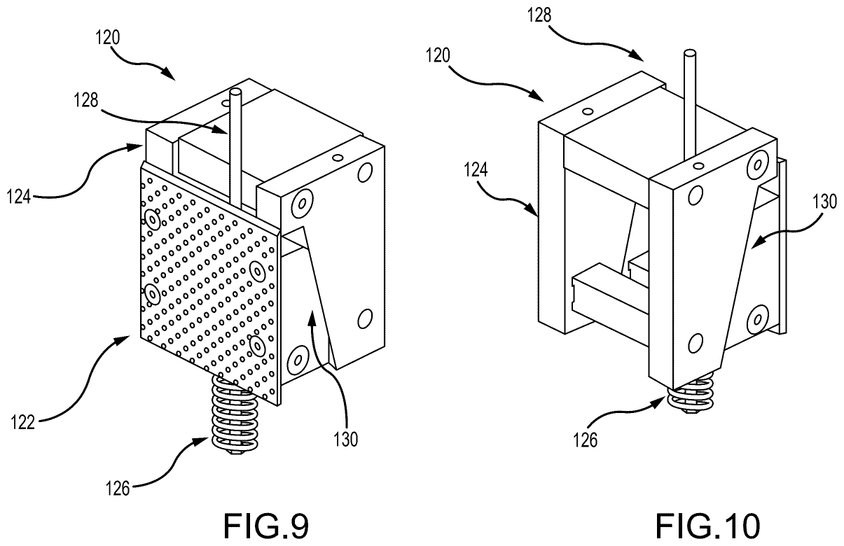

FIG. 11 is a side elevation view of a clamping bracket 120 according to an embodiment of the present disclosure. FIG. 12 is a rear elevation view of the clamping bracket of FIG. 11. FIG. 13 is a cross-sectional elevation view of the bracket of FIG. 11, and FIG. 14 is a detailed cross-sectional elevation taken at Detail A of FIG. 13. As shown, the bracket 120 comprises a clamping plate 122 and a main body portion wherein the clamping plate 122 is moveable at least relative to the main body portion 124. In at least some embodiments, the clamping plate 122 is biased by a biasing member 126 provided around a rod 128. In embodiments, the rod 128 comprises a threaded rod with at least one of a flange, washer, or shelf portion at a lower end to provide a surface to receive a first end of the biasing member. A contact surface (150 in FIG. 14) is provided as part of or in communication with the clamping plate 122 to receive a force from the biasing member 126. The clamping plate 122 is vertically and horizontally displaceable (at least with respect to the orientation shown in FIG. 11) relative to the main body portion 124.

As best shown in FIGS. 12 and 13, one or more lock nuts 129 are provided on the rod member 128 and provide for the ability to selectively control or lock out the movement of the clamping plate 122. For example, if and when it is desired to maintain the clamping plate 122 in a fully open position, the lock nut(s) are adjusted to a position that contact a bushing 154 and maintains the spring in a compressed state and wherein the clamping plate 122 is substantially prevented from moving to a locked or clamped position. In addition to comprising a lock out feature, the lock nut(s) 129 are further operable to control an amount of displacement that is achievable by the clamping plate 122. For example, the lock nut(s) 129 can serve as a limiter for an amount of upward and/or horizontal displacement that the plate 122 is capable of.

As shown in FIGS. 13-14, in one or more embodiments the rod member 128 extends through a bushing in the clamping plate. The bushing 154 comprises an internal void space 152 that allows the clamping plate 122 to move vertically and horizontally relative to the rod member 128 and the main body portion 124. As previously described, a movement of the clamping plate 122 is defined at least in part by the angle of the cammed or ramped surface 130 along which the clamping plate 122 moves in at least two axes. In order for the rod member 128 to remain stationary in a horizontal direction, the clamping plate 122 must be provided with some freedom of movement in this direction. Accordingly, the void space 152 is provided such that the clamping plate 122 is operable to move horizontally at least relative to the rod member 128.

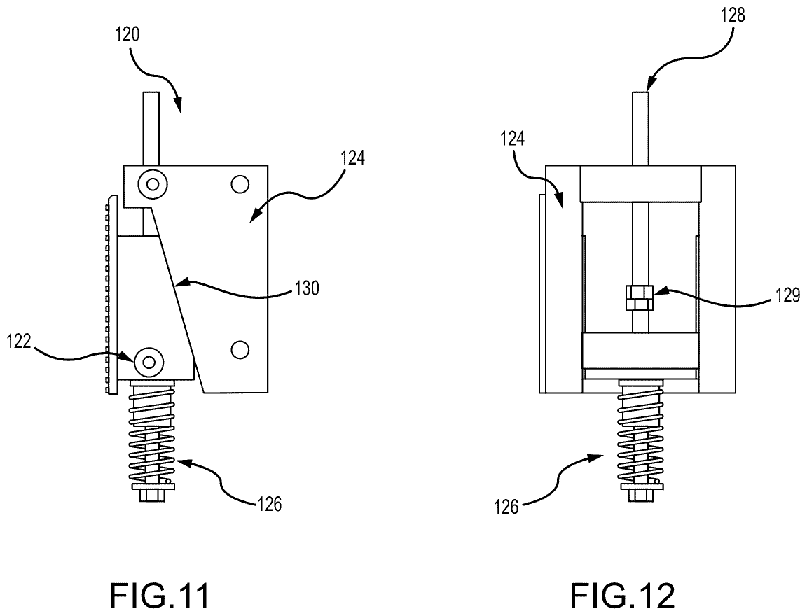

FIG. 15 is a perspective view of a data center 1 generally depicting an arrangement of equipment and a flow of thermal energy. As shown, the data center 1 comprises a plurality of cabinets and/or servers arranged in a manner wherein heat is dissipated from the servers into hot aisles 4. The hot aisles 5 comprise areas of increased thermal energy due to, for example, vented portions of adjacent cabinets facing the hot aisle(s) 5. One of ordinary skill in the art will understand that the energy is required to be conveyed from the hot aisles and cooled (e.g., via mechanical cooling) to maintain the server room or data center at an appropriate or desired temperature. Heat is therefore conveyed to one or more conduits or mechanical cooling units 7 where it is removed and/or cooled. Cool air 9 is delivered to the data center at one or more locations. Cold aisles 11 are provided that generally comprises areas of reduced temperatures at least relative to the hot aisles 4.

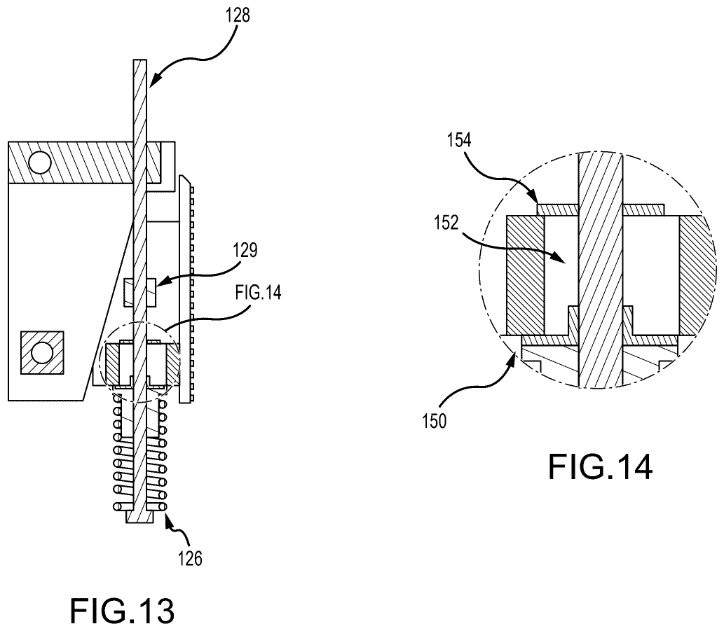

FIG. 16 is an elevation view again showing movement of air and thermal energy within a system 20. A plurality of servers 22 or similar devices is shown and the servers 22 produce heat and at least one associated hot aisle 24. Air is preferably conveyed away from the hot aisle 25 and vented and/or cooled. Cold return air is provided to maintain the system 21 at a desired temperature.

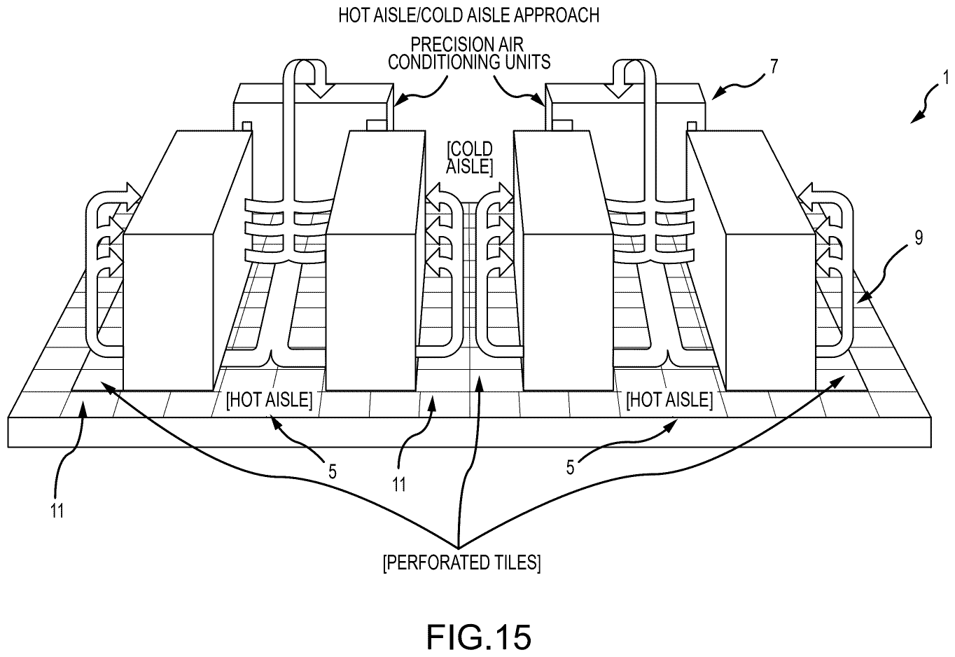

FIG. 17 is a perspective view of a data center 31 to further illustrate a movement of air and dissipation of thermal energy from a hot aisle 34. As shown in FIG. 3, a containment structure 36 is contemplated as being provided to aid in the conveyance of heat from a hot aisle 34. The containment structure may comprise various structures including fabricated hot aisle containment structures, drop ceilings, and other features to form a conduit for conveyance of heat from the hot aisle 34. The hot air from the hot aisle 34 is contemplated as being vented and/or cooled, and cool air 38 is returned to the data center 30.

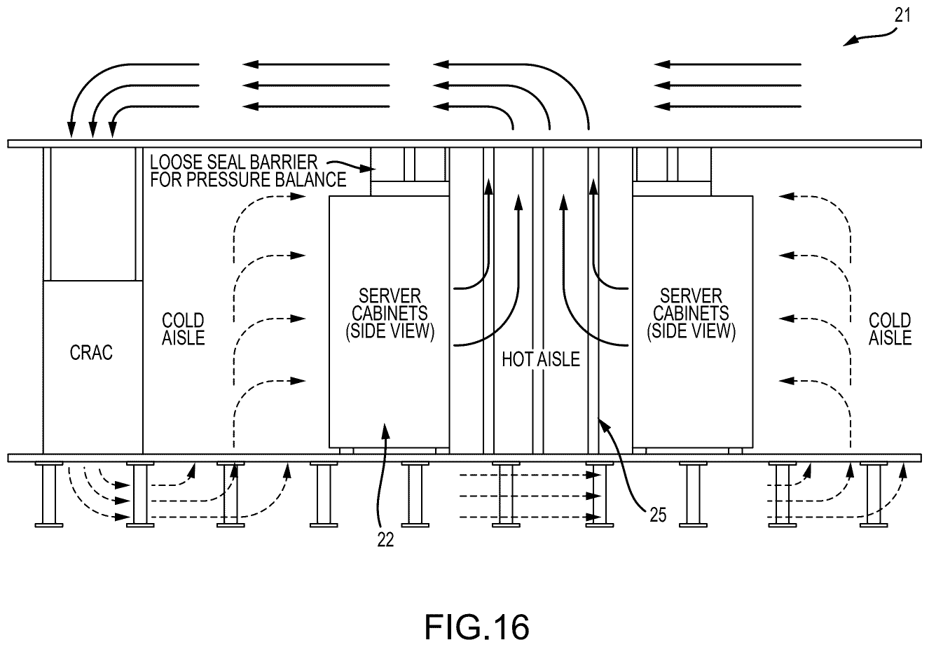

Referring now to FIG. 18, an installation method and sequence for a hot aisle containment structure 50 is provided. As shown in steps A through N, a hot aisle containment (“HAC”) structure 50 is provided and is preferably formed at least partially of wood or timber elements. At step A, a plurality of posts 52 (e.g., timber 4″×4″ posts) are erected. In some embodiments, the posts 52 are secured or anchored to the substrate by various devices and methods. Posts 52 are contemplated as being provided with a brace or anchor member, a pedestal (e.g., a concrete pedestal), implanted partially within the substrate, or otherwise secured. In alternative embodiments, the posts 52 are not anchored to the substrate and structural integrity is provided by the rigidity of the fully formed structure.

At step B, the posts 52 are fitted with transverse panels 56 and wherein a transverse panel(s) 56 that extends between each adjacent pair of posts 52. The transverse panels 56 are contemplated as comprising planar timber members. At step C, opposing longitudinal panels 58 are provided that extend substantially perpendicularly to the transverse panels 56, for example, between two individual posts 52 of different pairs. At step D, horizontal support members 60 are secured to an exterior of the partially assembled structure and cable trays 62 (or similar) are hung or supported by the support members 60. At step E, the assembled transverse panels 56, longitudinal panels 58, horizontal support member 60, and/or cable trays 62 are contemplated as being interconnected to one another but not yet secured to the posts 52. In some embodiments, cable trays 62 are not secured at this stage and may be installed after lifting (for example). It is also contemplated that certain embodiments of the present disclosure provide for structures that do not comprise cable trays.

As contemplated in Step E, the assembled or connection portions 56, 58, 60, 62 are then raised to a desired final position and secured to the posts 52 through various means and methods. The assembled structure is contemplated as being lifted or raised by, for example, one or more scissor lifts, forklifts, hydraulic jacks, winches, gantry lifts, cranes, backhoes or similar devices and/or equipment. It should be recognized, however, that no limitation is provided with respect to the devices and methods for lifting components. In some embodiments, for example, the structure may be lifted and manipulated through human power.

Steps F-J of FIG. 18 illustrate a fully formed section 72 of a HAC structure formed by the preceding steps A-E and wherein a second section 73 is constructed adjacent to the first section 71. The second section 73 is contemplated as being formed by substantially the same methods steps of the first section 71 and once completed and raised, the second section 73 may be secured to the first section (step J). Further sections may be formed by this method (steps K-N, for example) so as to construct a HAC unit 50 of a desired length. It should also be recognized that the sequence(s) of the process shown in FIG. 18 may be varied. For example, it is contemplated that steps A-D are performed for as many sections as are desired and all lifting and related anchoring operations are performed after ground-level construction operations are complete.

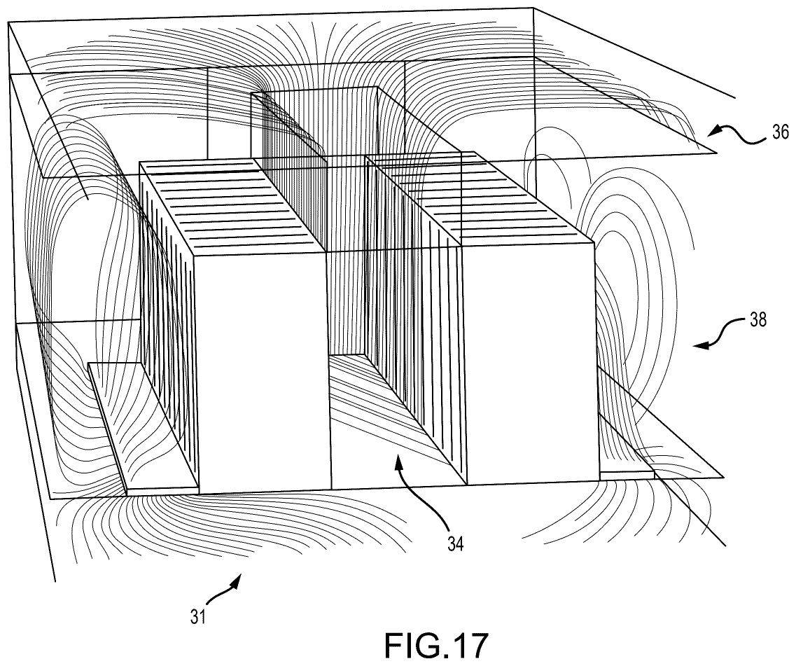

FIGS. 19A-19B are top plan and side elevation views of a HAC structure 91 and associated method of assembly of the same. As shown in step 1, a post or column 92 is provided in a substantially vertical position and is secured to a substrate (e.g., floor, slab, etc.). At step 2, a sleeve assembly 94 is provided that is operable to be provided with and/or communicate with the post 92. At step 3, the sleeve assembly 94 is temporarily secured to the post and is not fully secured such that the sleeve assembly 94 is allowed to move in at least one direction relative to the post (e.g., vertically). At step 4, a longitudinal panel 96 is provided that is operable to be provided and/or communicate with at least one of the sleeve assembly 94 and the post 92. In one or more embodiments, the sleeve assembly 94 comprises studs that are operable to communicate with and/or extend into or through the longitudinal panel 96. At steps 5 and 6, the panel 96 is positioned and bolted, fastened or otherwise secured onto the sleeve assembly 94. At step 7, support arms 98 and cable trays 101 are secured to the panel(s) 96 and/or sleeve(s) 94. At step 8, the structure, including the sleeve assembly 94, longitudinal panel(s) 96, arms 98 and/or cable trays 101, is displaced vertically to a desired location and position. At step 9, fasteners 103 are provided to clamp or otherwise secure the structure at its intended final position.

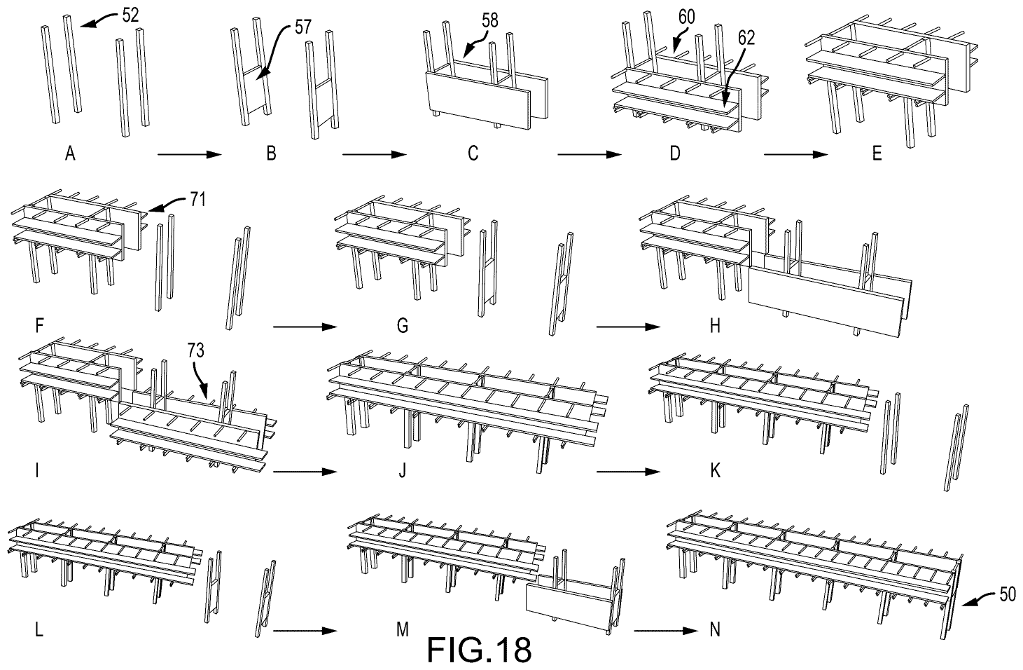

FIG. 20 provides elevation views of an assembly HAC structure according to one embodiment of the present disclosure. Various dimensions are provided in FIGS. 6A-6B in order to illustrate the sizing and proportions of one contemplated embodiment. It will be recognized, however, that no limitation with respect to size, dimensions, proportions, is provided herewith and HAC structures of the present disclosure may vary based on site-specific requirements, user-preferences, etc.

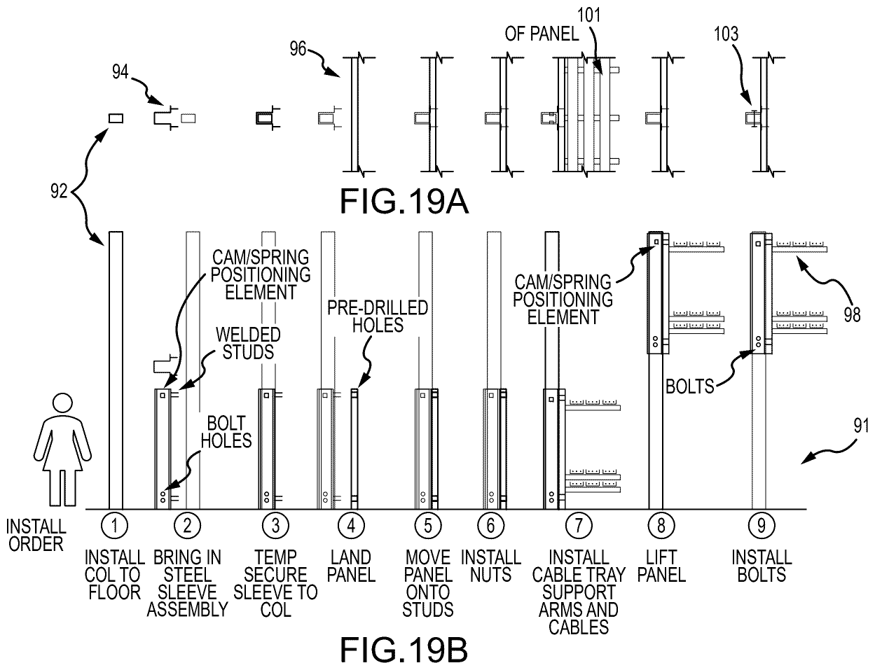

FIG. 21 is a top plan view of components of a HAC structure 121 including a plurality of columns 132a, 132b, 132c, 132d, transverse members 132a, 132b, longitudinal panels 132a, 136b, and connecting components related to the same. In various embodiments of the present disclosure including but not limited to FIG. 21, transverse members are contemplated as comprising structural support members that generally extend between or from longitudinal panels. In some embodiments, transverse members 134a, 134b comprise planar members extending between and substantially perpendicular to the longitudinal panels. It should be recognized, however, that transverse members 134a, 134b are not limited to this arrangement and may comprise various elements (e.g., angled 2×4 members, wooden truss arrangements, dowel rods, etc.) and various materials.

As shown, a sleeve member 138 is provided in communication with each of the columns 132. The sleeve members 138 are operable to surround a column of rectangular cross-sectional shape on three sides and further comprises flanges operable to extend along a portion of an interior face of a longitudinal panel 136. In at least one alternative embodiment, however, the sleeve members 138 comprise a cylindrical or semi-cylindrical shape and are operable to surround a column of a circular or substantially circular cross-sectional shape. Fasteners 131 are operable to be provided through the flanges to secure the sleeve member 138 and the longitudinal panel 136. A clamp member 133 is provided on an opposing side of the sleeve member 138 from the flanges and the clamp member 133 is operable to receive and secure a transverse panel 134. Additionally, a fastener 135 (e.g., a shear bolt) is contemplated as being provided through the sleeve member 138 and the column 132 to secure the sleeve 138 in a desired vertical position and support a weight of the assembly. A second bolt 133 is provided through the sleeve member 138 and the column 132 to secure the arrangement.

As shown in FIG. 21, for example, a hot aisle space is provided and is generally defined by the longitudinal panels 136. Transverse panels 134 are provided to supply structural and torsional stability to the system. In some embodiments, a HAC system is provided to vent or convey hot air upwardly and the transverse panels do not significantly impede air and heat transfer in such arrangements. In further embodiments, and although not shown in FIG. 21, one or more apertures, holes, or cut-outs are provided in the transverse panels 134a, 134b and air and heat are allowed to transmit through the transverse panels 134 and substantially parallel to the longitudinal panels 136. While various embodiments of the present disclosure contemplate and provide wood panel members (e.g., 134 in FIG. 21) extending between the longitudinal panels, alternative embodiments contemplate that torsional stability is provided to the longitudinal panels by alternative means and methods. For example, panels, bracing, beams, purlins, joists, girders, trusses, wires, cables, and similar features of various materials including wood and metal are contemplated as being provided. Embodiments of the present disclosure are thus not limited to panels or wood members extending within the HAC system. Similarly, although wood posts 132 are contemplated in various embodiments, vertical supports are contemplated as being formed of various structures and materials including, for example, metal beams, poles, jack posts, vertical trusses, concrete columns, etc.

As will be recognized by one of ordinary skill in the art, the warm air from the cabinets (at least relative to room ambient air) will generally rise vertically and no lower limit or floor member is required or provided in the HAC structure of FIG. 21. As shown, the conduit or guide members for the air and thermal energy in FIG. 21 are primarily provided by the longitudinal panels 126, which generally provide a path or conduit for warm air to be conveyed and cooled. In alternative embodiments, however, it is contemplated that the HAC structure comprises an at least partially closed lower surface. For example, the HAC structure is contemplated as comprising a rectilinear cube with a bottom and into which air is conveyed by one or more of ducts, vent fans, hoods, etc. from the cabinets.

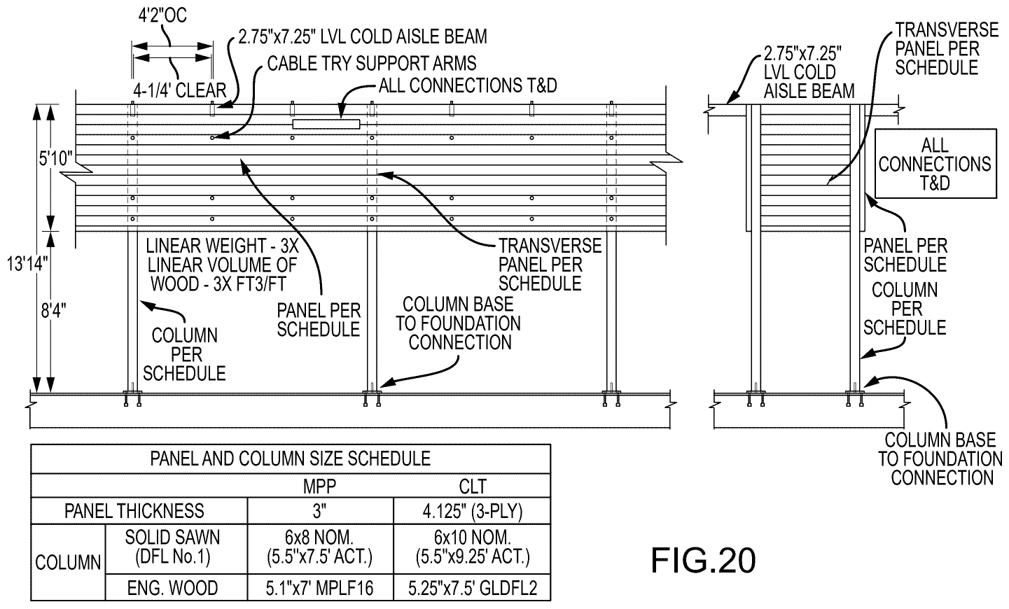

FIG. 22 is a perspective view of a HAC structure 140 according to another embodiment of the present disclosure. As shown, the HAC structure 140 of FIG. 22 comprises a timber structure and wherein a plurality of A-frame elements 142 are provided to vertically support a series of HAC units 144. A plurality of cabinets 146 are contemplated as being provided and the cabinets 146 are contemplated as housing computer hardware (e.g., servers) that generate heat. A hot aisle area is provided as a generally enclosed area that is characterized as a space between adjacent rows of cabinets. A door 148 is contemplated as being produced to maintain an enclosed space while allowing entry into the hot aisle area (e.g., for servicing equipment). The hot aisle area is in fluid communication with the HAC units 144 such that warm or hot air is allowed to vent (passively or by force) into the HAC units 144 where the air is substantially contained and may be conveyed as desired (e.g., via venting or mechanical cooling).

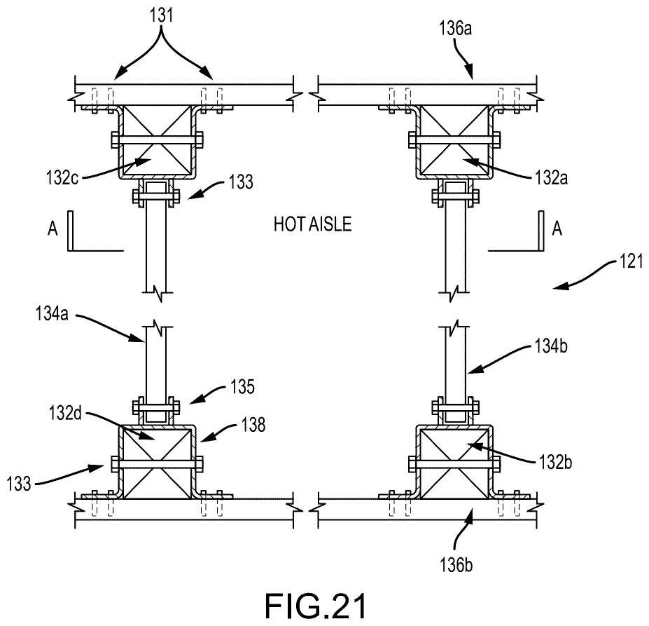

FIG. 23 provides a plurality of views of a modular column member 160 according to an embodiment of the present disclosure. In some embodiments, systems and methods for providing and erecting structures are contemplated wherein packing and shipping is required. It is further contemplated that structures (e.g., HAC and data center structures) are to be packed and shipped efficiently and wherein certain components are packed and shipped in an at least partially disassembled state. Components and features are then contemplated as being assembled on-site with relative ease and quickness. Accordingly, and as shown in FIG. 23, a multi-part column 160 is provided that comprises a first component 162a and a second component 162b. The first component comprises tongue 164 and a cammed surface 166. The second component 162b comprises a slot or groove 168 and a corresponding cammed surface 170. The first and second components 162a, 162b may be brought into connection with one another in a perpendicular relationship and rotated 90 degrees to form a column. Apertures 172 are provided in both the first and second components 162a, 162b to pin, fasten, or otherwise secure the components. Additionally, a sleeve or brace 174 is provided to provide the appropriate structural integrity and limit a risk of buckling when a load is placed on the column 160. The sleeve 174 is contemplated as being secured to the column 160 by the apertures 172 and/or by additional fasteners.

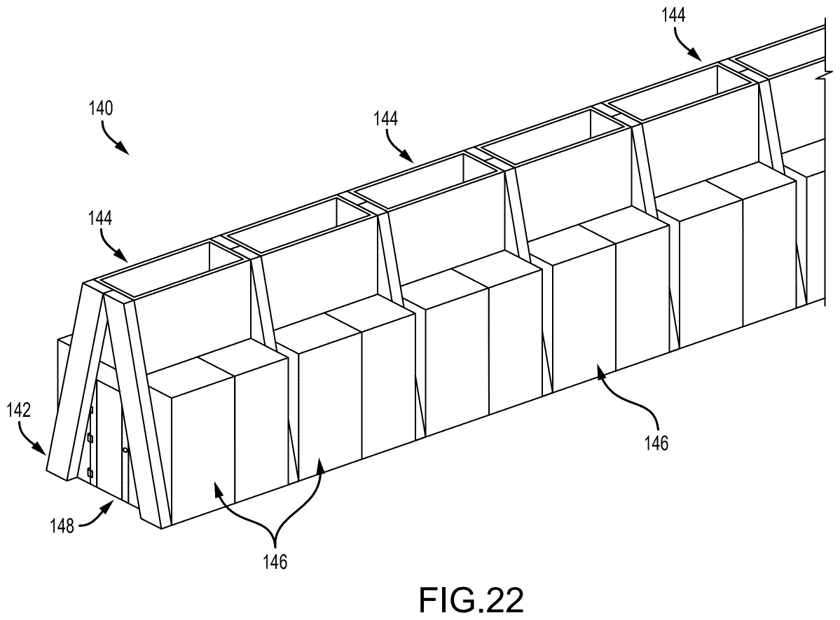

FIG. 24 provides views of a modular column 190 according to another embodiment of the present disclosure that is operable to efficiently packed, shipped, and erected on-site. As shown, the column 190 comprises hinges on opposing sides 192a, 192b of the column 190. The column 190 is contemplated as being hingedly connected and folded for shipping and is operable to be provided in an unfolded configuration upon installation. A first set of hinges 194a is contemplated as being secured to both sections of the column during shipping and allows for rotation of the column sections relative to one another. A second set of hinges 194b is either not connected or is partially connected during shipping and is fully secured to both column sections on-site to form a constructed column. A sleeve or brace (not shown in FIG. 24) is further contemplated as being provided to secure the hinged connection and provide additional structural integrity for the column 190.

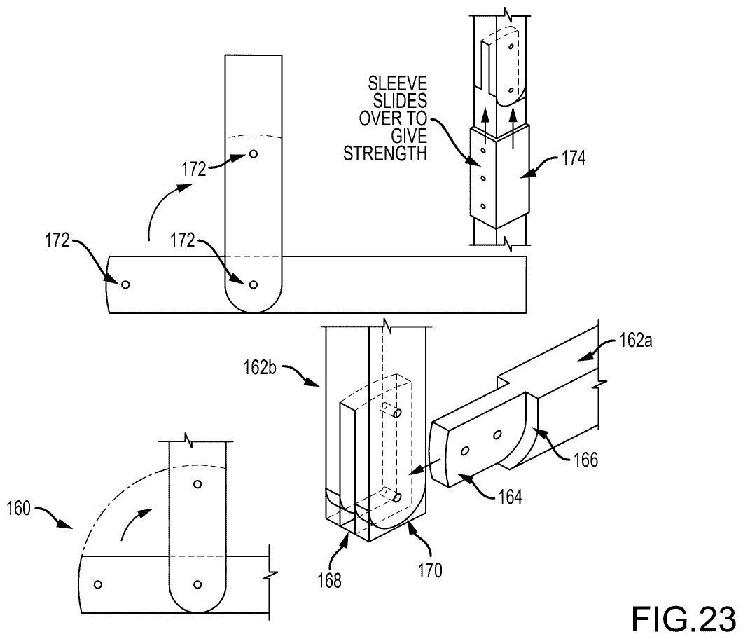

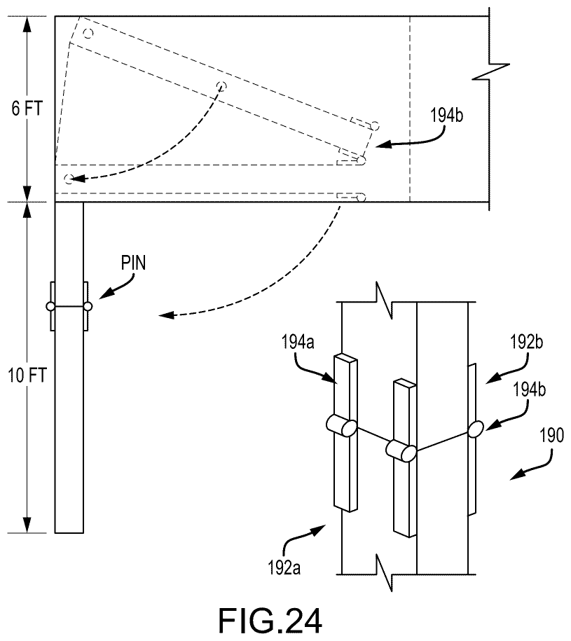

FIG. 25 is a top plan view of a sleeve member 200 according to an embodiment of the present disclosure. As shown, the sleeve member 200 comprises first and second L-shaped members 202a, 202b. The first and second members 202a, 202b are contemplated as being provided in contact and/or communication with a column or post of substantially rectangular (e.g., square) cross-sectional shaped. The members 202a, 202b are brought into contact with a column and are secured thereto. The sleeves of FIGS. 25 and 26 are contemplated for use with various columns, including but not limited to those shown in FIGS. 5, 7, 9 and 10, which may require additional structural support around a joint. It should be recognized, however, that sleeves are not solely contemplated for use with modular or jointed columns and may, for example, be provided on any column requiring additional support and enhanced buckling resistance.

FIG. 26 is a perspective view of a sleeve 210 according to another embodiment of the present disclosure. As shown, the sleeve 210 comprises first and second L-shaped members 212a, 212b. The first and second members 212a, 212b are contemplated as being provided in contact and communication with a column or post of substantially rectangular (e.g., square) cross-sectional shape. The members 212a, 212b are brought into contact with a column and are secured thereto. Flanges 214 and apertures 216 are provided on at least one of the members 212a and/or 212b to facilitate securing the members. A threaded bolt, for example, is contemplated as being provided in combination with a nut and wherein the threaded bolt extends through a first member 212a and a flange of the second member 212b such that a clamping force can be selectively provided to the sleeve 210 and any associated column.

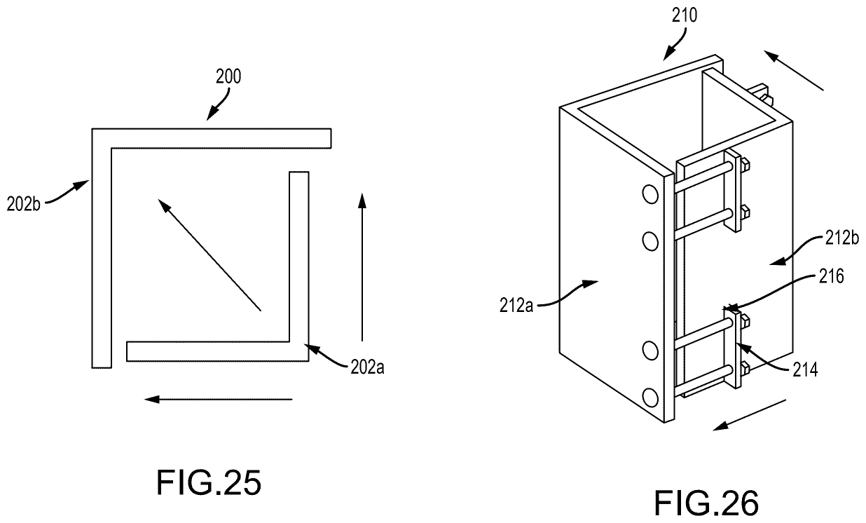

FIG. 27 is a top plan view of components of a HAC structure 220 according to an embodiment of the present disclosure. As shown, the structure 220 comprises at least one longitudinal panel 222 with first and second braces or sleeves 224a, 224b secured thereto. A column 226 is nested at least partially within the sleeve 224 prior to final installation to reduce the overall size of the structure during shipping and storage (for example). The columns 226 are contemplated as being unsecured to temporarily secured in a first state and are contemplated as being telescoping columns that can quickly be deployed on-site during assembly of the structure. A fastener 228 is provided for securing the longitudinal panel 222 and the sleeves 224 in a final relative position when desired (i.e., after lifting the HAC unit and the longitudinal panel into place). The sleeve 224 of FIG. 27 is contemplated as comprising a wooden structure (e.g., a glulam member).

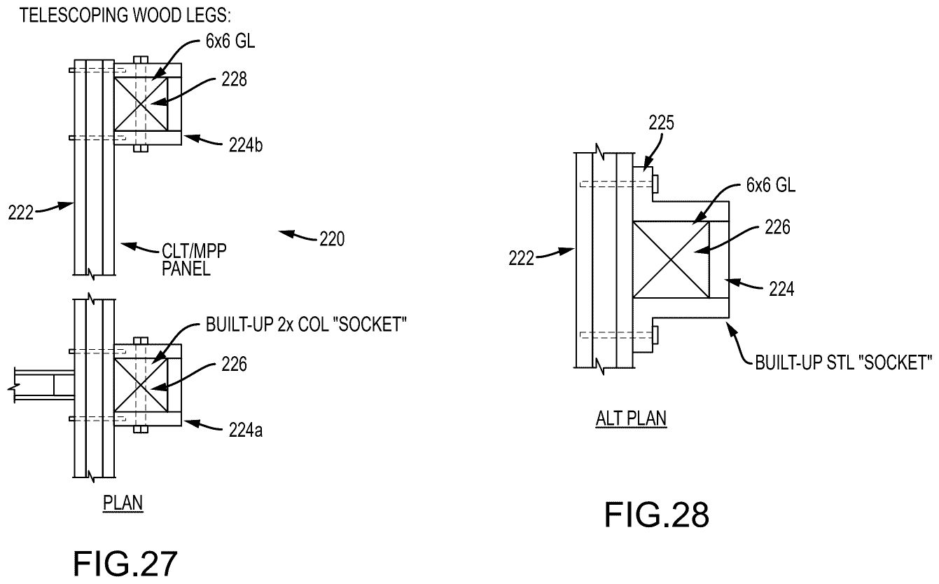

FIG. 28 is a top plan view of a sleeve 224 operable to communicate with a post member 226 and wherein the sleeve 224 is contemplated as comprising a metal sleeve. The sleeve 224 comprise a flange and bolt arrangement 226 to secure to a panel 222. The sleeve 224 and panel 222 are contemplated as translatable relative to the column 226 during a lifting operation and secured in place thereafter.

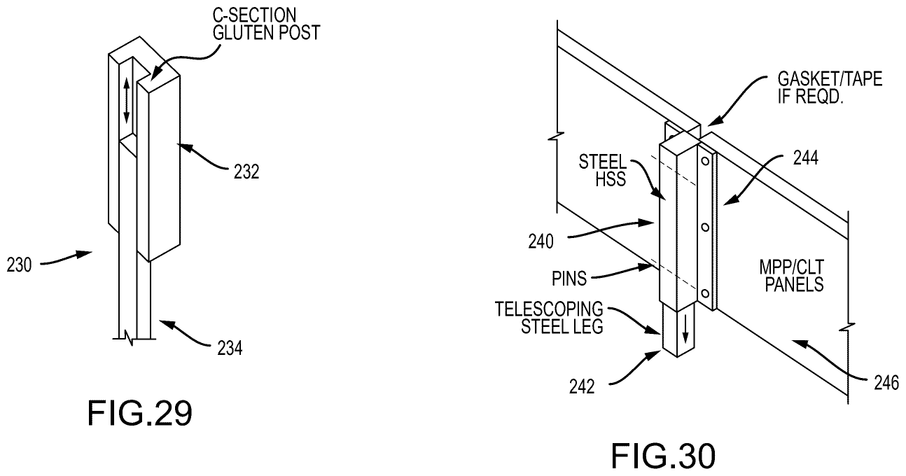

FIG. 29 is a perspective view of a component 230 of a HAC structure according to another embodiment of the present disclosure. As shown, the component 230 comprises a C-shaped sleeve 232 and a column 234. The column 234 is slidable or telescoping relative to the sleeve 232. The depicted components are contemplated as being shipped in a nested and contracted state and extended on-site to deploy columns for a HAC unit. The C-shaped sleeve 232 is contemplated as being secured to a HAC unit (e.g., directly to a longitudinal panel as shown and described herein).

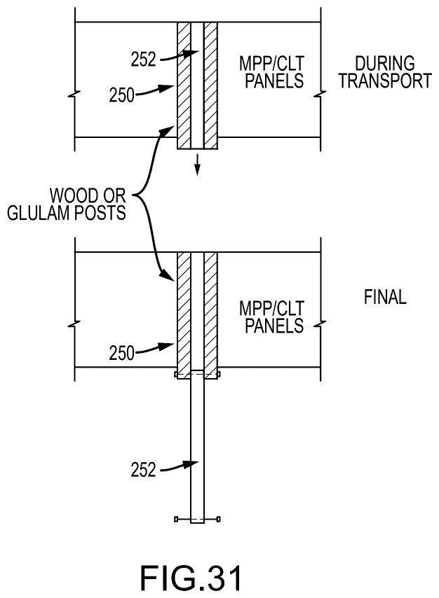

FIG. 30 is a perspective view of yet another embodiment of a sleeve 240 and an associated quickly deployable column 242. As shown, the sleeve 240 of FIG. 30 comprises an enclosed sleeve member with flanges 244 operable to secure to a panel 246. A post or column 242 is contemplated as being housed within the sleeve 242 and extended therefrom for installation.

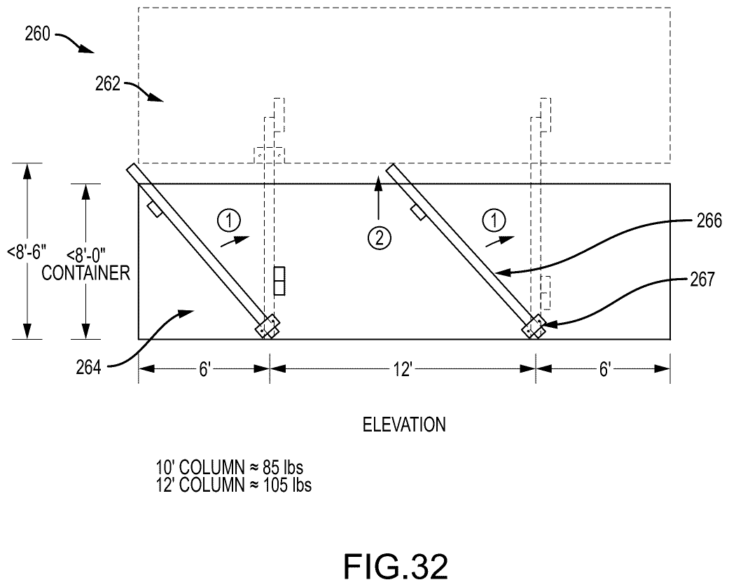

FIG. 31 provides elevation views of another embodiment wherein a sleeve 250 comprises wood of glulam members and a column 252 is at least initially stowed within the sleeve 250 (e.g., during transit). The column 252 can be extended or deployed from the sleeve for installation. The embodiments of FIGS. 29-31 are contemplated as comprising a column stowed within a component in a telescoping manner. The stowed column may comprise the total column height required for installation or may provide only a portion of the final column height. In the latter embodiments, additional column section(s) are contemplated as being secured to the column shown in FIGS. 29-31 to achieve a desired height.

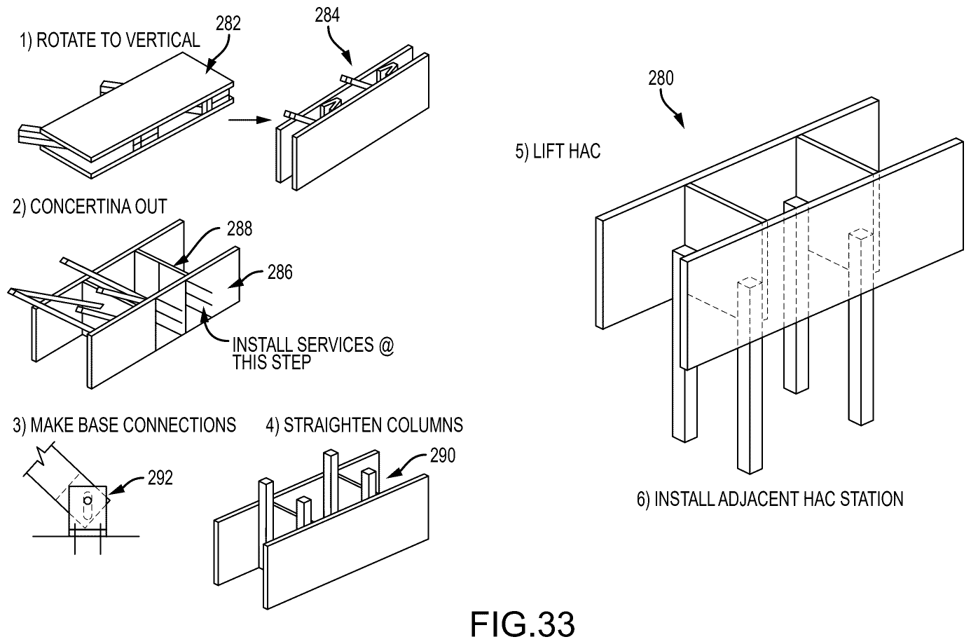

FIG. 32 is a side elevation view of a system and method for erecting a HAC structure 260 according to an embodiment of the present disclosure. As shown, a HAC containment area 262 is at least partially defined by one or more longitudinal panels 264. Columns 266 are provided and are contemplated as being rotated to a vertical position and secured to a substrate. In some embodiments, the columns 266 are rotatably secured to the panel 264 at or proximal to the base 267 of the column 266 for shipping and transportation. The column(s) 266 are rotated relative to the panel during installation and secured to the substrate. The HAC containment area 262 is then raised to a desired position and secured to the columns 266 by one or more of the various means, methods and systems shown and described herein.

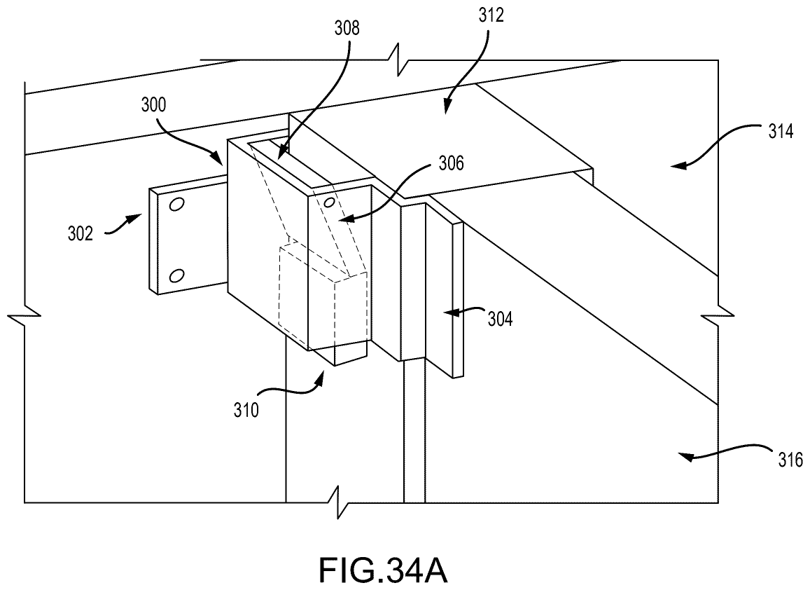

FIG. 33 illustrates a method of installing a HAC structure 280 according to an embodiment of the present disclosure. As shown, components of the system are shipped in a condensed or lay-flat arrangement 282. For installation, the structure 280 is provided in a vertical orientation 284. Longitudinal panels 286 are then spaced apart to a desired distance and transverse panels 288 are provided to both separate and secure the longitudinal panels 286. In some embodiments, the columns 290 are rotatably secured to the panel 286 at or proximal to the base of the column 290 for shipping and transportation. The column(s) 290 are rotated relative to the panel during installation and secured to the substrate. The columns 290 are then lifted and/or rotated to a vertical position (for example) and secured at their base. The panels 288, 286 are then lifted to a desired height and secured. Any number of additional HAC structures of the depicted embodiment or other embodiments and designs are then contemplated as being provided to achieve a desired size and arrangement for the HAC structure and data center.

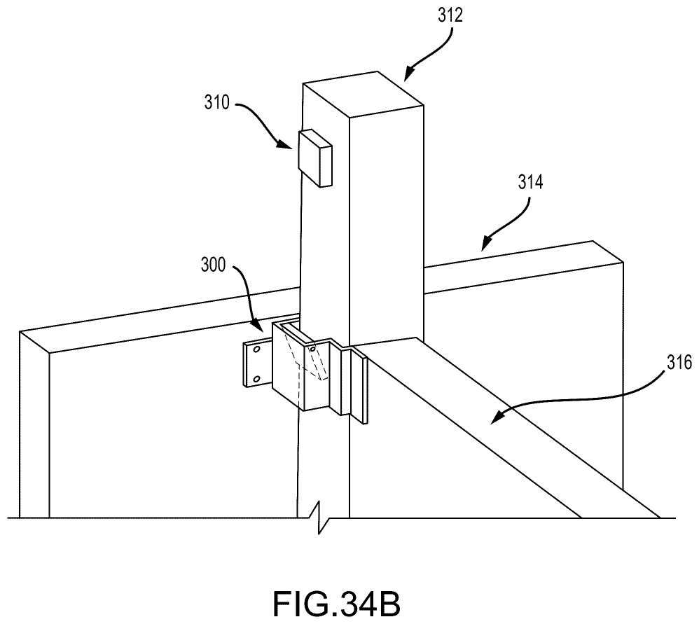

FIGS. 34A-34B are perspective views of a system according to an embodiment of the present disclosure wherein a bracket 300 and associated locking element 306 are provided. As shown, the bracket 300 is contemplated as being secured to and connecting at least one and preferably two or more panels 314, 316 that are to be raised and provided as a HAC structure or portion thereof. The bracket 300 comprises first and second flanges 302, 304 operable to receive fasteners and secure the bracket 300 to the panels. The bracket 300 further comprises an interior void that houses a locking element 306. The locking element generally comprises a cam or pawl with a spring-loaded hinge 308 that is operable to bias at least a distal end of the pawl toward a structure feature (e.g., a post 312). The post is further contemplated as comprising one or more stops in the form of at least one of a protrusion, an indentation, a tooth, and a ridge for receiving and communicating with the locking element 306. The angled and biased nature of the locking element allows for the locking element 306 to translate past the stop(s) 310 when the bracket 300 and any interconnected structures are displaced vertically upward and such that downward movement (at least past the stops 310) is generally prevented. In preferred embodiments, the bracket 300 and pawl 306 is contemplated as comprising a safety feature that is operable for use during lifting operations and the system requires additional hardware to secure the bracket in a final position. Alternatively, however, it is contemplated that the bracket 300 and pawl 306 system provides the necessary fastening and anchoring for the system and further securing is not required.

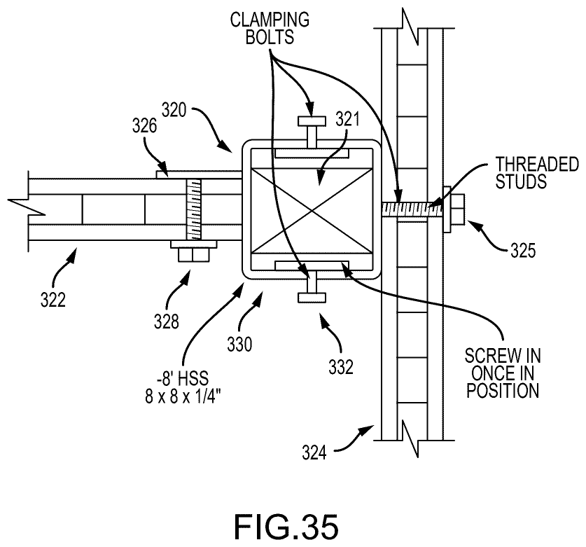

FIG. 35 is a top plan view of a securing system 320 according to one embodiment of the present disclosure. As shown, the system comprises a bracket with a body portion 330 that is operable to surround a post 321 (for example). The bracket is operable to secure a first panel 322 and a second panel 324. In embodiments, the bracket is operable to secure a first panel 322 transversely disposed to a second panel 324. The first and second panels may comprise, for example, a transverse panel and a longitudinal panel of a HAC unit. The body 330 comprises a flange or tab 326 that is operable to be provided in communication with a first panel 322 and secured thereto by a fastener, e.g., bolt 328. A fastener or second bolt 325 is operable to extend through the second panel 324 and secure the second panel 324 to the body portion 330. The system may be assembled as shown and with the first and second panels 322, 324 connected to the bracket system 320 but wherein the components are not fully secured to the post 321. The components may be collectively lifted or raised to a desired position whereupon clamp bolts 332 are tightened to secure the bracket and associated panels to the post at the desired height. The clamp bolts 332 may comprise pressure pads operable to communicate with the post and/or may penetrate a portion of the post.

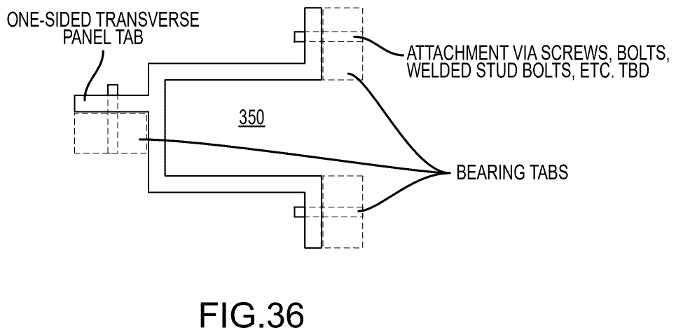

FIG. 36 is a top plan view of a bracket member according to another embodiment of the present disclosure. As shown, the bracket member comprises an internal void space 350 operable to surround and/or communicate with a structural member (e.g., wood post) and a plurality of tabs or flanges to communicate with and secure to panel members (for example).

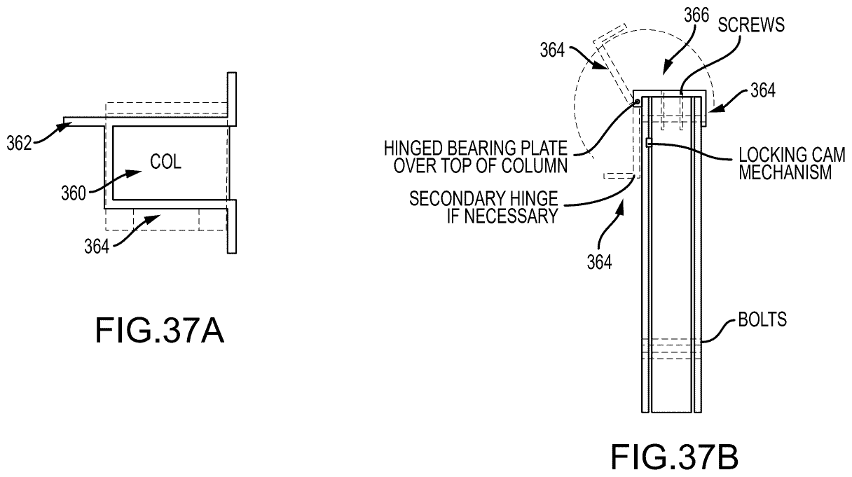

FIG. 37A is a top plan view of a column 360 with an associated bracket 362 comprising a hinged bearing plate 364 that is operable to be rotated into place once the bracket 362 and associated elements are raised to a desired final location. FIG. 37B is an elevation view of the system of FIG. 37A (and rotated 90 degrees) showing a rotation of the hinged bearing plate 364 and a final resting location wherein the hinged bearing plate 364 can be secured to a top surface of the post or column 360 by one or more fasteners 366. The hinged bearing plate 364 is operable to provide a protective member to cover the column and may comprise wood or metal.

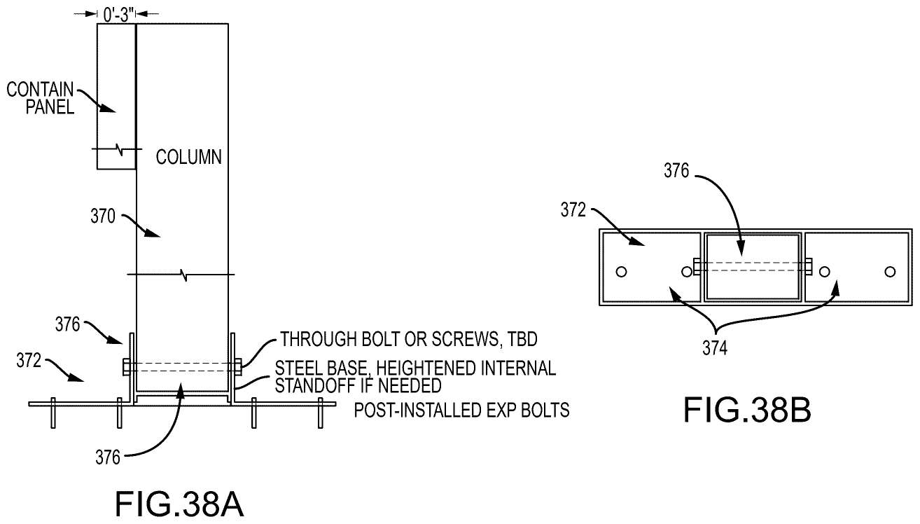

FIGS. 38A-38B provide an elevation view and a top plan view of a post member 370 and a substrate bracket 372 that is operable to secure the post member 370 to a floor or substrate. As shown, the substrate bracket comprises a first set of flanges 374 operable to connect to a substrate and a second set of flanges 376 operable to communicate with the post member 370. The first set of flanges 374 are contemplated as being anchored to a substrate by fasteners 378. A through bolt or similar fastener 380 is contemplated as securing the column 370. In some embodiments, a column 370 is provided with a rounded bottom portion that may installed or partially installed in a horizontal position and rotated to a vertical position. In such embodiments, a plurality of bolts 380 are provided to secure the column in the upright position.

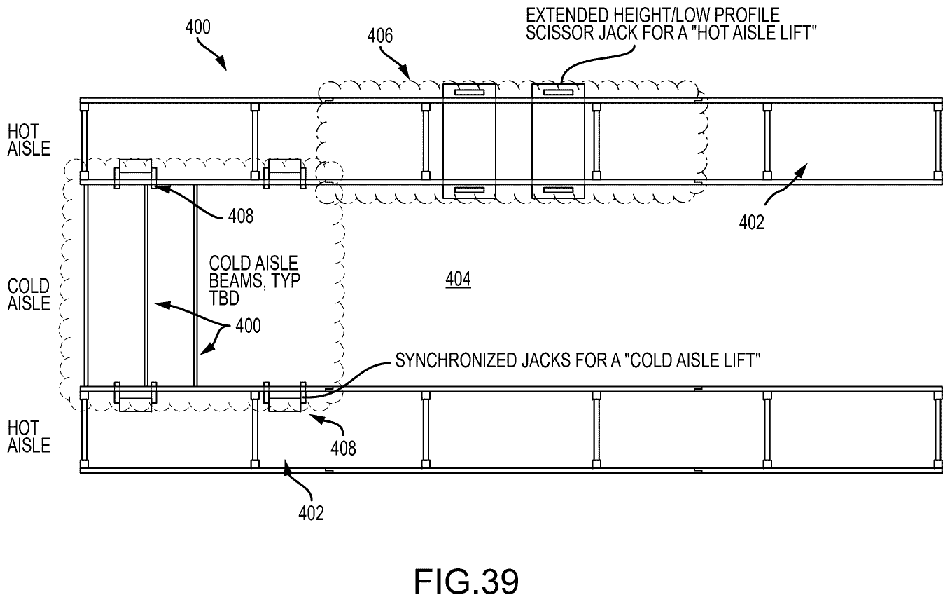

FIG. 39 is a top plan view of an installation 400 according to an embodiment of the present disclosure. As shown, the installation 400 comprises a plurality of HAC structures 402 with a cold aisle area 404 provided therebetween. It is contemplated that the HAC structures 402 are raised or lifted to a desired position after at least partial assembly by a lift such as a scissor jack system 406. A plurality of scissor jacks are contemplated as being provided based on at least one of the weight and length of the HAC structure to be raised. Cold aisle beams 408 are provided and are contemplated as being raised by a plurality of synchronized jacks 410. Cold aisle beams 408 are contemplated as spanning between the longitudinal panels of adjacent HAC units (i.e., across the cold aisle) and provide additional structural stability and support for any ceiling or plenum elements, lights, equipment, etc. that may be required for a complete assembly. The cold aisle is generally contemplated as being enclosed at one or both ends, and a door or similar access is contemplated as being provided to allow access and entry into the cold aisle.

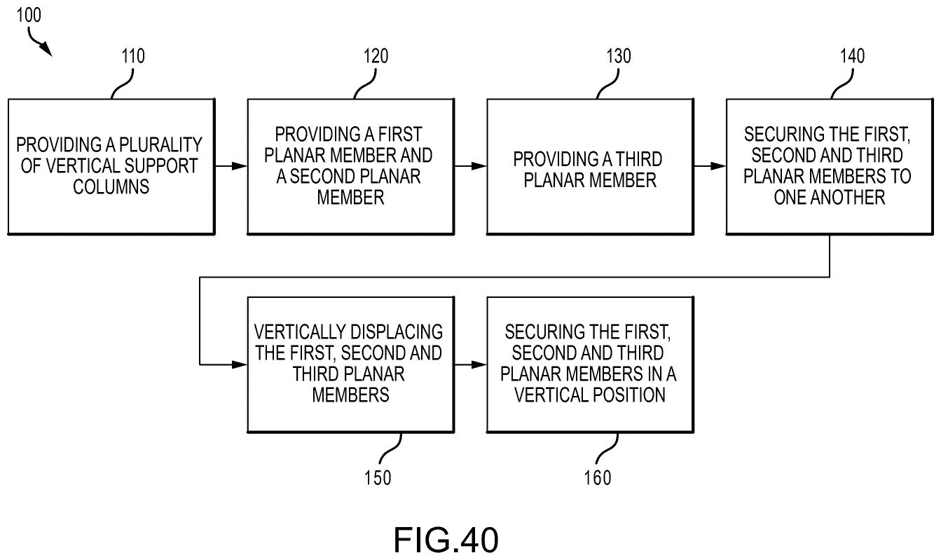

With reference to FIG. 40, embodiments of the present disclosure are further directed to a method 500 of constructing a hot air containment unit for a data center. As indicated at 510, the method 500 comprises providing a plurality of vertical support columns. As indicated at 520, the method 500 comprises providing a first planar member and a second planar member in a parallel and spaced apart configuration such that the first and second planar members at least partially define a volume for at least one of containing and conveying air. As indicated at 530, the method 504 further comprises providing a third planar member extending between the first and second planar members. As indicated at 540, in embodiments the method 500 comprises securing the first, second and third planar members to one another. As indicated at 550, in one or more embodiments the method 500 comprises vertically displacing the first, second and third planar members and the securing member to a desired vertical position. As indicated as 560, in embodiments the method 500 comprises securing the first, second and third planar members and the securing member in the desired vertical position.

In one or more embodiments of the method 500, the first, second and third planar members are secured to one another by a securing member. In embodiments of the method 500, the securing member at least partially surrounds a first one of the plurality of vertical support columns. In one or more embodiments of the method 500, the step of vertically displacing 560 comprises using at least one of a scissor lift, a jack, and a motorized lift to vertically displace the first, second and third planar members, and the securing member to a desired vertical position. In embodiments of the method 500, securing the first, second and third planar members and the securing member in the desired vertical position comprises providing and securing a fastener through at least one of the securing member and the first column. In one or more embodiments of the method 500, at least one of the first column, the first planar member, the second planar member and the third planar member comprise a wood material, and optionally, the wood material comprises a fire-retardant material.

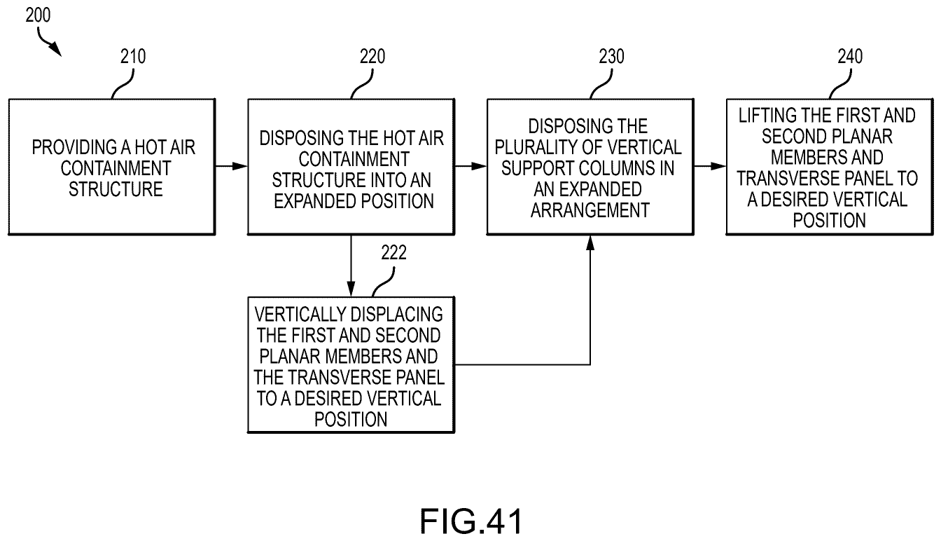

With reference to FIG. 41, embodiments of the present disclosure are also directed to a method 600 of installing a hot air containment structure for a data center. As indicated at 610, In embodiments the method 600 comprises providing a hot air containment structure that is disposable between a collapsed position into an expanded position. In one or more embodiments of the method 600, the hot air containment structure is provided in the collapsed position. In one or more embodiments of the method 600, the hot air containment structure comprises a first planar member and a second planar member disposed in a parallel configuration, a plurality of vertical support columns disposed between the first planar member and the second planar member, and at least one transverse panel disposed in a collapsed arrangement between the first planar member and the second planar member. In at least one embodiment of the method 600, the first planar member and the second planar member are adjacently disposed to the plurality of vertical support columns. In embodiments of the method 600, at least one of the plurality of vertical columns disposed next to at least one different and adjacent one of the plurality of vertical columns.

As shown at 620, the method 600 further comprises disposing the hot air containment structure into the expanded position. In embodiments, disposing the hot air containment structure into the expanded position 620 comprises 622 disposing the transverse panel into an extended orientation such that the first planar member and the second planar member are in a spaced apart relation to one another with the at least one transverse panel disposed between them.

As shown 630, in one or more embodiment the method 600 further comprises disposing the plurality of vertical support columns from an initial and at least partially folded arrangement into an expanded arrangement. In embodiments, disposing the plurality of vertical support columns from an initial and at least partially folded arrangement into an expanded arrangement 630 comprises at least a first of the plurality of vertical support columns being adjacently disposed to the first planar member and/or at least a second of the plurality of vertical support columns being adjacently disposed to the second planar member.

In one or more embodiments of the method 600, the transverse panel comprises a first segment pivotally movable to a second segment. In embodiments of the method 600, the first segment is pivotally movable to the first planar member and/or the second segment is pivotally movable to the second planar member. In embodiments of the method 600, the first planar member, the second planar member and/or the transverse panel are movable in a vertical direction relative to the plurality of vertical support columns.

As shown at 640, in one or more embodiments the method 600 further comprises lifting the first planar member, the second planar member and the transverse panel to a desired vertical position. In embodiments, the method 600 further comprises securing the first and second planar members and the transverse panel into a desired vertical position.

The examples set forth above are provided to give those of ordinary skill in the art a complete disclosure and description of how to make and use the embodiments of the methods for providing and erecting structures and are not intended to limit the scope of what the inventors regard as the scope of the disclosure. Modifications of the above-described modes for carrying out the disclosure can be used by persons of skill in the art and are intended to be within the scope of the following claims.

It is to be understood that the disclosure is not limited to particular methods or systems, which can, of course, vary. It is also to be understood that the terminology used herein is for the purpose of describing particular embodiments only and is not intended to be limiting.

A number of embodiments of the disclosure have been described. Nevertheless, it will be understood that various modifications may be made without departing from the spirit and scope of the present disclosure. Accordingly, other embodiments are within the scope of the following claims.

What is claimed is:

1. A clamping bracket for selective securement to a support, the clamping bracket comprising:
a main body portion;
a displaceable member comprising a planar surface operable to contact and apply force to the support;
wherein the main body portion comprises an angled surface and the displaceable member is slidingly translatable relative to the main body portion; and
a biasing member provided in communication with the displaceable member and operable to apply force to and displace the displaceable member at least in a first direction and secure the clamping bracket to the support.

2. The clamping bracket of claim 1, wherein the displaceable member is slidingly translatable relative to the main body portion along a contact surface formed by the angled surface and a portion of the displaceable member.

3. The clamping bracket of claim 2, wherein the contact surface comprises an angled bearing surface operable to direct a movement of the displaceable member.

4. The clamping bracket of claim 1, wherein the support comprises a column to which the clamping bracket is to be secured; the clamping bracket further comprising a plurality of interconnected members operable to surround the support.

5. The clamping bracket of claim 1, further comprising a rod member extending through the displaceable member and the main body portion and wherein the biasing member is provided in communication with the rod member.

6. The clamping bracket of claim 5, further comprising at least one fastener provided on the rod member and wherein the at least one fastener is operable to selectively limit a movement of the displaceable member.

7. The clamping bracket of claim 1, wherein the planar surface comprises at least one of a friction pad and a textured surface.

8. The clamping bracket of claim 1, further comprising a fastener that extends through the bracket and into a member to which the bracket is to be secured to provide an anchorage in addition to the planar surface.

9. A clamping bracket for selective securement to a vertical support member, the clamping bracket comprising:
a first portion comprising a first ramped surface;
a second portion that is displaceable relative to the first portion, the second portion comprising a planar surface operable to contact and apply force to the vertical support member to which the clamping bracket is to be secured;
wherein the second portion comprises a second ramped surface in force transmitting communication with the first ramped surface and the first portion;
a biasing member provided in communication with the second portion and operable to apply force to the second portion to displace the planar surface of the second portion in at least a first direction and secure the clamping bracket to the vertical support member.

10. The clamping bracket of claim 9, wherein first ramped surface and the second ramped surface comprise an angle of between approximately 45 and 80 degrees.

11. The clamping bracket of claim 9, wherein the first portion further comprises a plurality of interconnected members operable to surround the vertical support member.

12. The clamping bracket of claim 9, further comprising a rod member extending through the first portion and the second portion and wherein the biasing member is provided in communication with the rod member.

13. The clamping bracket of claim 12, further comprising at least one fastener provided on the rod member and wherein the at least one fastener is operable to selectively limit a movement of the displaceable member.

14. The clamping bracket of claim 9, further comprising a fastener that extends through the bracket and into a member to which the bracket is to be secured to provide an anchorage in addition to the planar surface.

15. The clamping bracket of claim 9, further comprising at least one of hangar and a bracket extending from the first portion.

16. The clamping bracket of claim 9, wherein the planar surface comprises a textured surface.

17. The clamping bracket of claim 9, further comprising a locking member provided on the threaded rod to selectively control a movement of the second portion.

18. The clamping bracket of claim 9, further comprising an aperture for receiving a fastener and wherein the clamping member is operable to be secured to an object by a clamping force and the fastener.

19. A system for containing or conveying air in a data center, the system comprising:
a plurality of vertical support columns;
a first planar member and a second planar member, wherein the first planar member and the second planar member comprises parallel spaced apart members at least partially defining a volume for at least one of containing and conveying air;
a third planar member extending between the first and second planar members;
wherein the third planar member is operable to provide stability to the system; and
wherein at least two of: one of the plurality of vertical support columns, the first planar member, and the third planar member are secured to one another by a clamping bracket.

20. The system of claim 19, wherein the clamping bracket comprises:
a main body portion;
a displaceable member comprising a planar surface operable to contact and apply force to the at least one of the plurality of vertical support columns,
wherein the main body portion comprises an angled surface and the displaceable member is slidingly translatable relative to the main body portion; and
a biasing member provided in communication with the displaceable member and operable to apply force to and displace the displaceable member at least in a first direction and secure the clamping bracket to the at least one of the plurality of vertical columns to which the clamping bracket is secured.
